(19) United States
(12) Patent Application Publication
(10) Pub. No.: US 2024/0397770 A1
(43) Pub. Date: Nov. 28, 2024

(54) DISPLAY APPARATUS

(71) Applicant: Semiconductor Energy Laboratory Co., Ltd., Atsugi-shi, Kanagawa-ken (JP)

(72) Inventors: Hidetomo KOBAYASHI, Isehara (JP); Hideaki SHISHIDO, Atsugi (JP); Daiki NAKAMURA, Atsugi (JP); Yuichi YANAGISAWA, Atsugi (JP)

(21) Appl. No.: 18/693,614

(22) PCT Filed: Sep. 21, 2022
(86) PCT No.: PCT/IB2022/058899

§ 371 Date: Mar. 20, 2024

(30) Foreign Application Priority Data
Sep. 30, 2021 (JP) 2021-161367

(51) Int. Cl. H10K 59/131; H10K 50/11; H10K 59/124; H10K 59/35

(52) U.S. Cl. CPC H10K 59/131; H10K 59/124; H10K 59/353; H10K 50/11

(57) ABSTRACT

A high-definition display apparatus is provided. A display apparatus with low power consumption is provided. A display apparatus with high luminance is provided. A display apparatus with a high aperture ratio is provided. The display apparatus includes a first wiring, a second wiring, a third wiring, and a pixel electrode. The first wiring extends in a first direction and is supplied with a source signal. The second wiring extends in a second direction intersecting with the first direction and is supplied with a gate signal. A constant potential is applied to the third wiring. In addition, the first wiring and the pixel electrode are provided to overlap with each other with the third wiring therebetween. An insulating layer includes a portion in contact with part of a top surface of the pixel electrode and a portion in contact with a side surface of the pixel electrode. An EL layer includes a first portion in contact with another part of the top surface of the pixel electrode and a second portion positioned over the insulating layer. The second portion includes a region whose thickness is half or less of thickness of the first portion.

### TECHNICAL FIELD

One embodiment of the present invention relates to a display apparatus. One embodiment of the present invention relates to an electronic device including a display apparatus.

Note that one embodiment of the present invention is not limited to the above technical field. Examples of the technical field of one embodiment of the present invention disclosed in this specification and the like include a semiconductor device, a display apparatus, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

In recent years, the resolution of display panels has been increased. For example, as devices requiring high-definition display panels, devices for virtual reality (VR) or augmented reality (AR) have been actively developed in recent years.

In addition, typical examples of a display apparatus that can be employed for a display panel include a liquid crystal display apparatus; a light-emitting apparatus including a light-emitting element such as an organic EL (Electro Luminescence) element or a light-emitting diode (LED); and electronic paper performing display by an electrophoretic method or the like.

The basic structure of an organic EL element is a structure where a layer containing a light-emitting organic compound is sandwiched between a pair of electrodes. By applying voltage to this element, light emission can be obtained from the light-emitting organic compound.

A display apparatus employing such an organic EL element does not need a backlight that is necessary for a liquid crystal display apparatus or the like; thus, a thin, lightweight, high-contrast, and low-power display apparatus can be achieved. Patent Document 1, for example, discloses an example of a display apparatus using an organic EL element.

### REFERENCE

### Patent Document

[Patent Document 1] Japanese Published Patent Application No. 2002-324673

### SUMMARY OF THE INVENTION

### Problems to be Solved by the Invention

In the above device for VR or AR that is wearable, a lens for focus adjustment needs to be provided between eyes and the display panel.

Since part of a screen is enlarged by the lens, the low definition of the display panel might cause a problem of weak sense of reality and immersion.

In addition, in the case of a battery-driven device, the power consumption of the display panel needs to be reduced in order that the continuous use time can be prolonged. Furthermore, in particular, a transmissive device for AR is required to have high luminance for displaying an image that is overlaid on external light.

One object of one embodiment of the present invention is to provide a high-definition display apparatus. One object of one embodiment of the present invention is to provide a display apparatus with low power consumption. One object of one embodiment of the present invention is to provide a display apparatus with high luminance. One object of one embodiment of the present invention is to provide a display apparatus with a high aperture ratio. One object of one embodiment of the present invention is to provide a highly reliable display apparatus.

One object of one embodiment of the present invention is to provide a novel display apparatus, display module, or electronic device. Another object of one embodiment of the present invention is to provide a method for manufacturing the above display apparatus with high yield. One object of one embodiment of the present invention is to at least reduce at least one of problems of a conventional technique.

Note that the description of these objects does not preclude the presence of other objects. Note that in one embodiment of the present invention, there is no need to achieve all these objects. Note that objects other than these can be derived from the description of the specification, the drawings, the claim s, and the like.

### Means for Solving the Problems

One embodiment of the present invention is a display apparatus including a first wiring, a second wiring, a third wiring, a pixel electrode, an EL layer, and an insulating layer. The first wiring extends in a first direction and is supplied with a source signal. The second wiring extends in a second direction intersecting with the first direction and is supplied with a gate signal. A constant potential is applied to the third wiring. In addition, the first wiring and the pixel electrode are provided to overlap with each other with the third wiring therebetween. The insulating layer includes a portion in contact with part of a top surface of the pixel electrode and a portion in contact with a side surface of the pixel electrode. The EL layer includes a first portion in contact with another part of the top surface of the pixel electrode and a second portion positioned over the insulating layer. The second portion includes a region whose thickness is half or less of thickness of the first portion.

Another embodiment of the present invention is a display apparatus including a first wiring, a second wiring, a third wiring, a pixel electrode, a first transistor, a second transistor, an EL layer, and an insulating layer. The first wiring extends in a first direction and is supplied with a source signal. The second wiring extends in a second direction intersecting with the first direction and is supplied with a gate signal. A first potential is applied to the third wiring. The first wiring and the pixel electrode are provided to overlap with each other with the third wiring therebetween. One of a source and a drain of the first transistor is electrically connected to the first wiring, and a gate of the first transistor is electrically connected to the second wiring. One of a source and a drain of the second transistor is electrically connected to the pixel electrode, and the other of the source and the drain of the second transistor is electrically connected to the third wiring. In addition, the first transistor and the second transistor each include a semiconductor layer in which current flows in the first direction. The insulating layer includes a portion in contact with part of a top surface of the pixel electrode and a portion in contact with a side surface of the pixel electrode. The EL layer includes a first portion in contact with another part of the top surface of the pixel electrode and a second portion positioned over the insulating layer. The second portion includes a region whose thickness is half or less of thickness of the first portion.

Another embodiment of the present invention is a display apparatus including a first wiring, a second wiring, a third wiring, a pixel electrode, a first transistor, a second transistor, an EL layer, and an insulating layer. The first wiring extends in a first direction and is supplied with a source signal. The second wiring extends in a second direction intersecting with the first direction and is supplied with a gate signal. A first potential is applied to the third wiring. The first wiring and the pixel electrode are provided to overlap with each other with the third wiring therebetween. One of a source and a drain of the first transistor is electrically connected to the first wiring, and a gate of the first transistor is electrically connected to the second wiring. One of a source and a drain of the second transistor is electrically connected to the pixel electrode, and the other of the source and the drain of the second transistor is electrically connected to the third wiring. The first transistor and the second transistor each include a semiconductor layer in which current flows in the second direction. The insulating layer includes a portion in contact with part of a top surface of the pixel electrode and a portion in contact with a side surface of the pixel electrode. The EL layer includes a first portion in contact with another part of the top surface of the pixel electrode and a second portion positioned over the insulating layer. The second portion includes a region whose thickness is half or less of thickness of the first portion.

In addition, in the above, a plurality of dummy layers are preferably included. In that case, it is preferable that the dummy layer contain the same semiconductor material as the semiconductor layer and that the dummy layer include a portion having substantially the same top surface shape as the semiconductor layer. Furthermore, it is preferable that the plurality of dummy layers and the semiconductor layer be placed at a regular interval in the second direction or the first direction.

In addition, in any of the above, the display apparatus preferably includes a fourth wiring, a third transistor, and a fourth transistor. One of a source and a drain of the third transistor is electrically connected to the fourth wiring, and the other of the source and the drain of the third transistor is electrically connected to a gate of the second transistor. One of a source and a drain of the fourth transistor is electrically connected to the fourth wiring, and the other of the source and the drain of the fourth transistor is electrically connected to the pixel electrode. Furthermore, a second potential lower than the first potential is applied to the fourth wiring.

In addition, in any of the above, the display apparatus preferably includes a fifth transistor. The fifth transistor is a transistor whose channel is formed in silicon. Furthermore, the semiconductor layer contains one or both of indium and zinc. Moreover, the first transistor and the second transistor are preferably provided above the fifth transistor.

In addition, in any of the above, the third wiring preferably has a grid-like top surface shape. In that case, the third wiring preferably includes a third portion extending in the first direction and a fourth portion extending in the second direction. Furthermore, the pixel electrode and the first wiring are preferably provided to overlap with each other with the third portion therebetween.

In addition, in any of the above, the display apparatus preferably includes a plurality of pixel electrodes. A light-emitting region is provided over each of the pixel electrodes. The plurality of light-emitting regions are preferably arranged so that one of the light-emitting regions is surrounded by six of the light-emitting regions in a plan view.

In addition, in the above, the light-emitting region preferably has a substantially hexagonal top surface shape. Furthermore, it is preferable that the light-emitting region have a top surface shape in which interior angles of two opposite corners of six corners are each greater than 1200 and interior angles of the other four of the six corners are each less than 120°.

Alternatively, in the above, the light-emitting region preferably has a substantially hexagonal top surface shape. Furthermore, it is preferable that the pixel electrode have a top surface shape in which six interior angles are each 120°, lengths of two opposite sides of six sides are equal to each other, and lengths of the other four sides are equal to one another.

In addition, in any of the above, three adjacent light-emitting regions of the light-emitting regions are preferably positioned to be on vertices of an isosceles triangle.

Another embodiment of the present invention is a display module including any of the above display apparatuses and a connector or an integrated circuit.

Another embodiment of the present invention is an electronic device including the above display module and at least one of an antenna, a battery, a housing, a camera, a speaker, a microphone, a touch sensor, and an operation button.

### Effect of the Invention

According to one embodiment of the present invention, a high-definition display apparatus can be provided. Alternatively, a display apparatus with low power consumption can be provided. Alternatively, a display apparatus with high luminance can be provided. Alternatively, a display apparatus with a high aperture ratio can be provided. Alternatively, a highly reliable display apparatus can be provided.

Alternatively, according to one embodiment of the present invention, a novel display apparatus, display module, electronic device, or the like can be provided. Alternatively, a method for manufacturing the above display apparatus with high yield can be provided. Alternatively, at least one of problems of a conventional technique can be at least reduced.

Note that the description of these effects does not preclude the presence of other effects. Note that one embodiment of the present invention does not necessarily have all the effects. Note that other effects can be derived from the description of the specification, the drawings, the claim s, and the like.

### BRIEF DESCRIPTION OF THE DRAWINGS

FIG. 1A to FIG. 1C are diagrams illustrating structure examples of display apparatuses.

FIG. 2 is a diagram illustrating a structure example of a display apparatus.

FIG. 3A to FIG. 3E are diagrams illustrating structure examples of the display apparatus.

FIG. 4A to FIG. 4E are diagrams illustrating structure examples of a display apparatus.

FIG. 5A to FIG. 5E are diagrams illustrating structure examples of a display apparatus.

FIG. 6A to FIG. 6D are diagrams illustrating structure examples of a display apparatus.

FIG. 7 is a diagram illustrating a structure example of a display apparatus.

FIG. 8A to FIG. 8F are diagrams illustrating structure examples of the display apparatus.

FIG. 9A to FIG. 9F are diagrams illustrating structure examples of a display apparatus.

FIG. 10A to FIG. 10D are circuit diagrams illustrating structure examples of the display apparatus.

FIG. 11A to FIG. 11D are circuit diagrams illustrating structure examples of the display apparatus.

FIG. 12 is a timing chart showing an example of a method for driving a display apparatus.

FIG. 13 is a diagram illustrating a structure example of a display apparatus.

FIG. 14 is a diagram illustrating a structure example of the display apparatus.

FIG. 15A to FIG. 15D are diagrams illustrating structure examples of the display apparatus.

FIG. 16 is a diagram illustrating a structure example of a display apparatus.

FIG. 17 is a diagram illustrating a structure example of a display apparatus.

FIG. 18 is a diagram illustrating a structure example of a display apparatus.

FIG. 19A to FIG. 19D are circuit diagrams illustrating structure examples of protection circuits.

FIG. 20A and FIG. 20B are diagrams illustrating structure examples of a display apparatus.

FIG. 21 is a diagram illustrating a structure example of the display apparatus.

FIG. 22A to FIG. 22C are diagrams illustrating structure examples of the display apparatus.

FIG. 23A to FIG. 23F are diagrams illustrating structure examples of a light-emitting device.

FIG. 24A to FIG. 24C are diagrams illustrating structure examples of the light-emitting device.

FIG. 25A and FIG. 25B are diagrams illustrating a structure example of an electronic device.

FIG. 26A and FIG. 26B are diagrams illustrating a structure example of an electronic device.

FIG. 27A to FIG. 27D are cross-sectional images of a display panel according to Example.

FIG. 28 is a top-view image of the display panel according to Example.

FIG. 29 is a chromaticity diagram according to Example.

FIG. 30A and FIG. 30B show spectra measurement results according to Example.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in structures of the present invention described below, the same reference numerals are commonly used for the same portions or portions having similar functions in different drawings, and a repeated description thereof is omitted. Moreover, similar functions are denoted by the same hatching pattern and are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that ordinal numbers such as “first” and “second” in this specification are used in order to avoid confusion among components and do not limit the number of components.

Note that in this specification and the like, a top surface shape of a component means an outline shape of the component in a plan view. In addition, a plan view means that the component is observed from a normal direction of a surface where the component is formed or from a normal direction of a surface of a support (e.g., a substrate) where the component is formed.

Note that in this specification and the like, the expression “top surface shapes are substantially the same” means that at least outlines of stacked layers partly overlap with each other. For example, the case of processing an upper layer and a lower layer with the use of the same mask pattern or mask patterns that are partly the same is included. However, in some cases, the outlines do not exactly overlap with each other and the upper layer is positioned on an inner side of the lower layer or the upper layer is positioned on an outer side of the lower layer; such a case is also represented by the expression “top surface shapes are substantially the same.”

Note that expressions indicating directions such as “over” and “under” are basically used to correspond to the directions of drawings. However, in some cases, the direction indicating “over” or “under” in the specification does not correspond to the direction in the drawings for the purpose of description simplicity, for example. For example, when a stacking order (or formation order) of a stacked body or the like is described, even in the case where a surface on which the stacked body is provided (a formation surface, a support surface, an adhesion surface, a planar surface, or the like) is positioned above the stacked body in the drawings, the direction and an opposite direction are expressed using “under” and “over,” respectively, in some cases.

Note that in this specification, an EL layer refers to a layer that contains at least a light-emitting substance (also referred to as a light-emitting layer) or a stack including the light-emitting layer provided between a pair of electrodes of a light-emitting element.

In this specification and the like, a display panel that is one embodiment of a display apparatus has a function of displaying (outputting), for example, an image on (to) a display surface. Therefore, the display panel is one embodiment of an output device.

Furthermore, in this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

### Embodiment 1

In this embodiment, structure examples of display apparatuses according to one embodiment of the present invention will be described.

One embodiment of the present invention is a display apparatus including a plurality of pixels arranged in a matrix. The display apparatus includes a plurality of source lines (first wirings) supplied with source signals (also referred to as video signals, data signals, or the like) and a plurality of gate lines (second wirings) supplied with gate signals (also referred to as scan signals or the like). The source lines are provided to extend in a first direction, and the gate lines are provided to extend in a second direction intersecting with the first direction.

Each pixel is provided for an intersection portion of one source line and one gate line. The pixel includes one or more display elements and one or more transistors. The pixel includes a pixel electrode that functions as an electrode of the display element.

Here, when electrical noise that is caused by a signal supplied to the source line, the gate line, or another wiring is transmitted to the pixel electrode, the potential of the pixel electrode might be changed and the gray level of the pixel might be deviated from an intended value. As a result, the display quality of an image displayed by the display apparatus is impaired. In particular, the frequency of a signal input to the source line is higher than that of a signal input to the gate line and thus greatly affects the potential of the pixel electrode.

As a measure to reduce electrical crosstalk between the source line and the pixel electrode, physically separating the pixel electrode from the source line is considered. In particular, preventing the source line and the pixel electrode from overlapping with each other is effective in reducing the crosstalk. However, such a method requires a reduction in the size of the pixel electrode, which leads to a decrease in the aperture ratio (effective light-emitting area ratio) of the display apparatus.

Thus, in one embodiment of the present invention, the source line and the pixel electrode overlap with each other with a wiring (a third wiring) to which a constant potential is applied therebetween. Accordingly, electrical noise from the source line is blocked by the third wiring, so that the electrical noise can be inhibited from being transmitted to the pixel electrode. Therefore, the area of the pixel electrode can be expanded and the aperture ratio of the display apparatus can be increased.

It is preferable that the third wiring be a wiring that supplies a constant potential to the pixel. For example, in the case where an organic EL element is used as the display element, the third wiring can also serve as a wiring that supplies an anode potential or a cathode potential to the organic EL element. In addition, the third wiring can also serve as a wiring that supplies a power supply potential (a high-power supply potential (VDD), a low-power supply potential (VSS), or the like) to the pixel.

The third wiring can have a striped top surface shape that extends along the first direction where the source lines extend. Furthermore, the third wiring may have a portion that extends along the second direction and may have a grid-like top surface shape that includes a portion along the first direction and a portion along the second direction.

In addition, in the case where the pixels are placed at high density, the distance between adjacent light-emitting elements needs to be decreased. Here, it can be said that a structure where color display is performed using a light-emitting element that emits white light and a color filter is suitable for higher definition because a layer containing a light-emitting compound (an EL layer) can be shared between adjacent light-emitting elements and thus there is no need to form EL layers separately. However, in the case where the distance between the adjacent light-emitting elements is small, unintended light emission might occur due to leakage current flowing between adjacent pixels through the EL layer. As a result, a decrease in color reproducibility, a color shift, a decrease in contrast, and the like occur.

Thus, in one embodiment of the present invention, a region where the EL layer is thin is formed between the adjacent pixels so that leakage current flowing through the EL layer is suppressed. Alternatively, a region where the EL layer is divided is formed between the adjacent pixels so that leakage current flowing through the EL layer is suppressed. In that case, a structure where the EL layer is thinned down or divided in a self-aligning manner when an organic layer or the like to be the EL layer is deposited is used. Accordingly, leakage current flowing through the EL layer can be suppressed or prevented without an increase in the number of steps, so that a display apparatus with high color reproducibility and high contrast can be achieved.

Specifically, a top surface of an insulating layer (also referred to as a partition) that covers an end portion of the pixel electrode is formed to have a concave shape. In that case, part of a surface of the insulating layer in contact with the EL layer is formed to be substantially perpendicular. Specifically, the surface of the insulating layer includes part in contact with the EL layer at greater than or equal to 700 and less than or equal to 120°, preferably greater than or equal to 750 and less than or equal to 115°, further preferably greater than or equal to 800 and less than or equal to 1100 with respect to a substrate surface or a top surface of the pixel electrode. For example, the insulating layer with such a top surface can be manufactured by processing the pixel electrode so that a side surface of the pixel electrode is substantially perpendicular and forming the insulating layer so that the insulating layer covers the side surface of the pixel electrode. With the use of such an insulating layer, the EL layer formed over the insulating layer is formed to have a thin portion or divided in a self-aligning manner.

For example, the EL layer in a region overlapping with the insulating layer has a locally thinner portion than other regions. Specifically, the EL layer in a portion overlapping with the insulating layer has a region whose thickness is half or less, preferably 40% or less, further preferably 30% or less and greater than 0% of the thickness of the EL layer in a portion overlapping with the pixel electrode. Accordingly, current flowing between the adjacent light-emitting elements through the EL layer can be suppressed.

Such a structure can inhibit the influence of electrical crosstalk between the pixel electrode and the wirings including the source line, so that the pixel electrode and the wirings can be freely placed to overlap with each other, and leakage current flowing between the adjacent light-emitting elements can be suppressed. Thus, a display apparatus with extremely high definition can be achieved. For example, it is possible to achieve a display apparatus with a definition higher than or equal to 1000 ppi, higher than or equal to 2000 ppi, higher than or equal to 3000 ppi, higher than or equal to 4000 ppi, or higher than or equal to 5000 ppi and lower than or equal to 30000 ppi, lower than or equal to 20000 ppi, or lower than or equal to 15000 ppi.

More specific examples are described below with reference to drawings.

### Structure Example 1

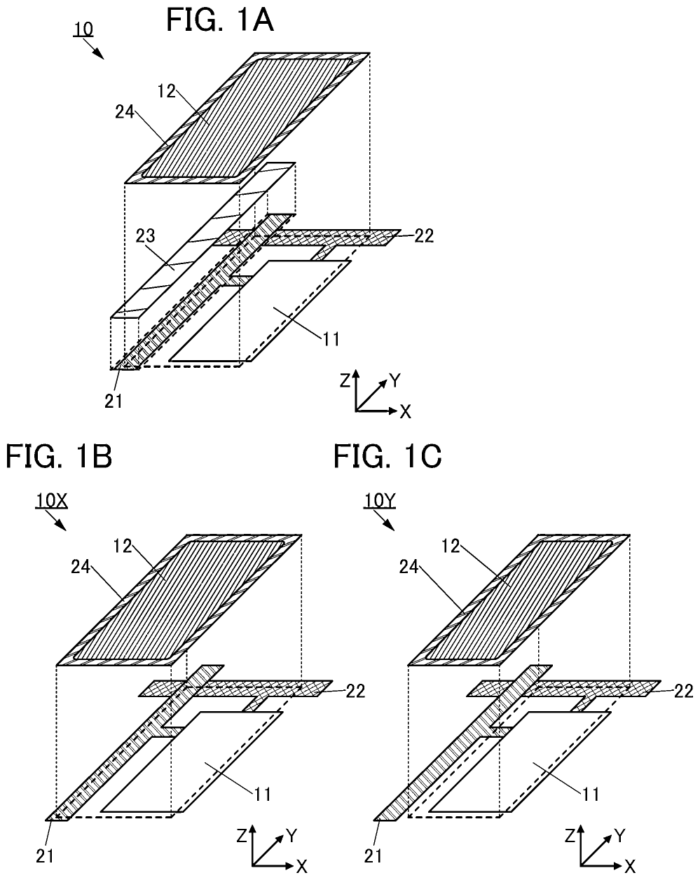

FIG. 1A is a schematic perspective view illustrating a stacked-layer structure of one subpixel in a display apparatus 10. The subpixel includes a pixel circuit 11, a light-emitting element 12, a wiring 21, a wiring 22, and a wiring 23. The light-emitting element 12 includes a pixel electrode 24. In addition, FIG. 1A shows an X direction, a Y direction, and a Z direction. The X direction, the Y direction, and the Z direction are directions orthogonal to each other.

The wiring 21 is a wiring that functions as a source line and extends in the Y direction. The wiring 22 is a wiring that functions as a gate line and extends in the X direction. The wiring 23 is a wiring that is supplied with a constant potential and includes a portion extending in the Y direction.

The light-emitting element 12 is provided inside the pixel electrode 24. As the light-emitting element 12, for example, an electroluminescent element in which a layer containing a light-emitting substance (also referred to as an EL layer) is sandwiched between a pair of electrodes and light is emitted when current flows between the pair of electrodes can be suitably used. In particular, an organic EL element using a light-emitting organic compound is preferably employed for the EL layer.

The pixel circuit 11 is a circuit for controlling current that flows to the light-emitting element 12. The pixel circuit 11 preferably includes one or more transistors.

The pixel electrode 24 and the wiring 21 include a region where they overlap with each other in a plan view. Furthermore, the pixel electrode 24 and the wiring 21 overlap with each other with the wiring 23 therebetween. By placing the wiring 23 supplied with a constant potential between the pixel electrode 24 and the wiring 21 in this manner, electrical noise due to the wiring 21 is blocked by the wiring 23 and prevented from being transmitted to the pixel electrode 24 even when the pixel electrode 24 and the wiring 21 are placed to overlap with each other. Accordingly, the area of the pixel electrode 24 can be expanded, and therefore, the light-emitting area of the light-emitting element 12 can be expanded and the aperture ratio (effective light-emitting area ratio) of the display apparatus 10 can be increased.

Here, a plan view refers to a view from the display surface side of the display apparatus 10.

FIG. 1B illustrates an example of a display apparatus 10X when the wiring 23 is not provided. In that case, deviation of the gray level in the light emission luminance of the light-emitting element 12 might occur when electrical noise from the wiring 21 is transmitted to the pixel electrode 24 positioned above the wiring 21 and the potential of the pixel electrode 24 is changed.

In addition, FIG. 1C illustrates an example of a display apparatus 10Y when the width of the pixel electrode 24 in the X direction is reduced so that the pixel electrode 24 does not overlap with the wiring 21. In that case, although crosstalk due to electrical noise from the wiring 21 can be suppressed, the light-emitting area of the light-emitting element 12 is decreased, so that the aperture ratio of the display apparatus 10 is reduced.

As described above, the display apparatus 10 according to one embodiment of the present invention can have high definition and a high aperture ratio. In addition, since the aperture ratio can be increased, luminance can be increased. Furthermore, current required for desired luminance can be reduced, so that a display apparatus with low power consumption where light-emitting element degradation is suppressed can be achieved.

### Structure Example 2

A more specific structure example of a pixel is described below.

### Structure Example 2-1

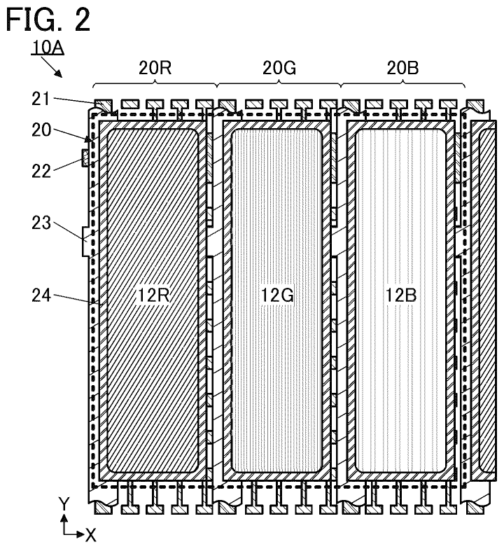

FIG. 2 illustrates a schematic top view of a pixel 20 included in a display apparatus 10A. The pixel 20 includes a subpixel 20R, a subpixel 20G, and a subpixel 20B. The display apparatus 10A includes a plurality of pixels 20 that are periodically placed in the X direction and the Y direction.

The subpixel 20R includes a light-emitting element 12R that emits red light. The subpixel 20G includes a light-emitting element 12G that emits green light. The subpixel 20B includes a light-emitting element 12B that emits blue light.

The light-emitting element 12R, the light-emitting element 12G, and the light-emitting element 12B may contain different light-emitting materials from each other, may each have a structure with a combination of a light-emitting element that emits white light and a color filter, or may each have a structure with a combination of a blue or violet light-emitting element and a color conversion material (a quantum dot or the like).

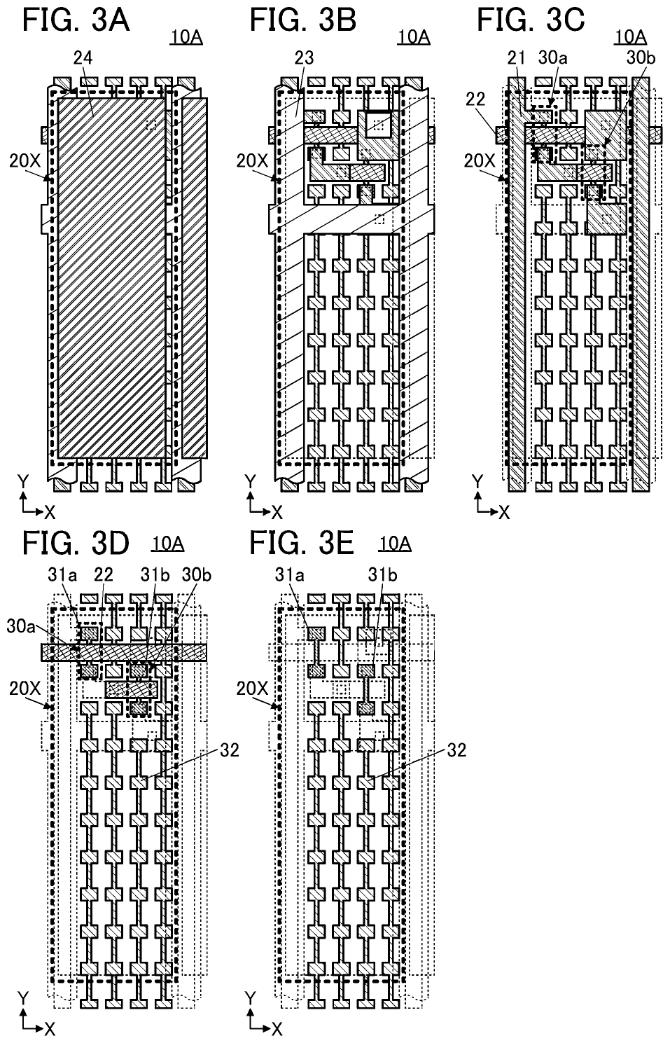

FIG. 3A to FIG. 3E each illustrate a schematic top view of one subpixel 20X included in the pixel 20 illustrated in FIG. 2. The subpixel 20X can be employed as the subpixel 20R, the subpixel 20G, and the subpixel 20B. Note that the light-emitting element is omitted here.

In FIG. 3B, only the outline of the pixel electrode 24 illustrated in FIG. 3A is clearly indicated by a dashed line, and FIG. 3B illustrates an example of a top surface shape of the wiring 23.

The wiring 23 functions as a power supply line for the light-emitting element 12, and a constant potential is applied to the wiring 23. In the case where the pixel electrode 24 functions as an anode, a high-power supply potential is applied to the wiring 23. In the case where the pixel electrode 24 functions as a cathode, a low-power supply potential is applied to the wiring 23.

As illustrated in FIG. 3B, it is preferable that the wiring 23 include not only a portion extending in the Y direction but also a portion extending in the X direction. Thus, the wiring 23 can have a grid-like top surface shape, so that the influence of a voltage drop can be inhibited because electrical resistance is lowered compared with the case where the wiring 23 has a striped top surface shape.

In FIG. 3C, only the outline of the wiring 23 in FIG. 3B is clearly indicated by a dashed line. In FIG. 3C, the same hatching pattern is used to illustrate the wiring 22 and a conductive layer formed by processing the same conductive film as the wiring 22. Similarly, in FIG. 3C, the same hatching pattern is used to illustrate the wiring 21 and a conductive layer formed by processing the same conductive film as the wiring 21.

In FIG. 3D, only the outlines of the wiring 21 in FIG. 3C and the conductive layer formed by processing the same conductive film as the wiring 21 are clearly indicated by dashed lines. In FIG. 3E, only the outlines of the wiring 22 in FIG. 3D and the conductive layer formed by processing the same conductive film as the wiring 22 are clearly indicated by dashed lines.

FIG. 3C and FIG. 3D each illustrate a transistor 30a and a transistor 30b. FIG. 3D also illustrates a semiconductor layer 31a included in the transistor 30a and a semiconductor layer 31b included in the transistor 30b. The transistor 30a functions as a selection transistor that controls selection/non-selection of the subpixel. In addition, the transistor 30b functions as a drive transistor that controls current flowing to the light-emitting element.

Part of the wiring 22 constitutes a gate of the transistor 30a, one of a source and a drain of the transistor 30a is electrically connected to the wiring 21, and the other of the source and the drain of the transistor 30a is electrically connected to a gate of the transistor 30b. One of a source and a drain of the transistor 30b is electrically connected to the wiring 23, and the other of the source and the drain of the transistor 30b is electrically connected to the pixel electrode 24.

In the example described here, each of top surface shapes of the semiconductor layer 31a and the semiconductor layer 31b includes a pair of thick portions where contact portions are placed and a thin portion formed as a channel. The semiconductor layers of the two transistors are preferably formed to have substantially the same top surface shapes in this manner because the electrical characteristic of the transistors can be uniform and designing is facilitated. Note that a transistor with desired electrical characteristics can be formed with a combination of semiconductor layers of the same pattern. For example, a structure may be employed in which a plurality of semiconductor layers are placed in parallel and connected in one transistor so that the channel width of the transistor is an integral multiple of that of the other transistor. Alternatively, a structure may be employed in which a plurality of semiconductor layers are placed in series and connected in one transistor so that the channel length of the transistor is an integral multiple of that of the other transistor.

In addition, in the display apparatus 10A, the semiconductor layer 31a included in the transistor 30a and the semiconductor layer 31b included in the transistor 30b are each placed so that current flows in the Y direction, i.e., a direction parallel to a direction in which the wiring 21 extends. In other words, the transistor 30a and the transistor 30b are each placed so that the channel length direction thereof is parallel to the Y direction and the channel width direction thereof is parallel to the X direction. In this manner, the direction of current flowing in the transistor is preferably aligned between the plurality of transistors included in the pixel because variation in the electrical characteristics can be suppressed and the designing can be facilitated.

Here, as illustrated in FIG. 3D and the like, a plurality of dummy layers 32 are preferably provided. The dummy layers 32 are formed by processing the same film as the semiconductor layer 31a and the semiconductor layer 31b, and can be films having the same composition as the semiconductor layer 31a and the semiconductor layer 31b. Note that in FIG. 3A to FIG. 3E, different hatching patterns are used to illustrate the semiconductor layer 31a and the semiconductor layer 31b, and the dummy layers 32 in order to distinguish the semiconductor layer 31a and the semiconductor layer 31b from the dummy layers 32.

A top surface shape of the dummy layer 32 is preferably the same as the top surface shape of each of the semiconductor layer 31a and the semiconductor layer 31b or a shape in which the top surface shapes of the semiconductor layer 31a and the semiconductor layer 31b are periodically combined. In the display apparatus 10A, one of the dummy layers 32 has a top surface shape that includes two or more thick portions and a thin portion connecting two adjacent thick portions in the Y direction. The dummy layers 32 are placed so that the longitudinal direction thereof is parallel to the Y direction. Furthermore, one dummy layer 32 is placed across a plurality of pixels arranged in the Y direction.

In this manner, when the dummy layers 32 are placed in a region where neither the semiconductor layer 31a nor the semiconductor layer 31b is provided, variation in processing shapes of the semiconductor layer 31a and the semiconductor layer 31b can be reduced and thus variation in the electrical characteristics of the transistor 30a and the transistor 30b can be reduced. Note that a dummy layer is a layer that is provided in a vacant space for the purposes of stabilization of a manufacturing process, a reduction in processing variation, and the like, and is basically not considered as a component of the circuit. For this reason, a dummy layer is electrically floating or constant voltage is applied to the dummy layer. Note that a dummy layer is preferably provided for a layer other than the semiconductor layer.

The dummy layers 32 are preferably placed as many as possible to be laid out over the region where neither the semiconductor layer 31a nor the semiconductor layer 31b is provided. Although the display apparatus 10A is an example where the dummy layers 32 are placed in a region other than a region where the wiring 21 is provided, the dummy layers 32 may be placed to overlap with the wiring 21.

Note that although two transistors are placed in one subpixel in this example, one embodiment of the present invention is not limited thereto, and three or more transistors may be placed. In that case, it is preferable that semiconductor layers of all the transistors included in the subpixel have the same patterns and that the directions of current flowing to the semiconductor layers be aligned with each other.

The above is the description of Structure Example 2-1.

A structure example whose structure is partly different from that of the above is described below with reference to drawings. Note that the description of portions similar to those described above is omitted below in some cases. In addition, in the drawings shown below, components having the same functions are denoted by the same hatching patterns and reference numerals, and the description thereof is omitted in some cases.

### Structure Example 2-2

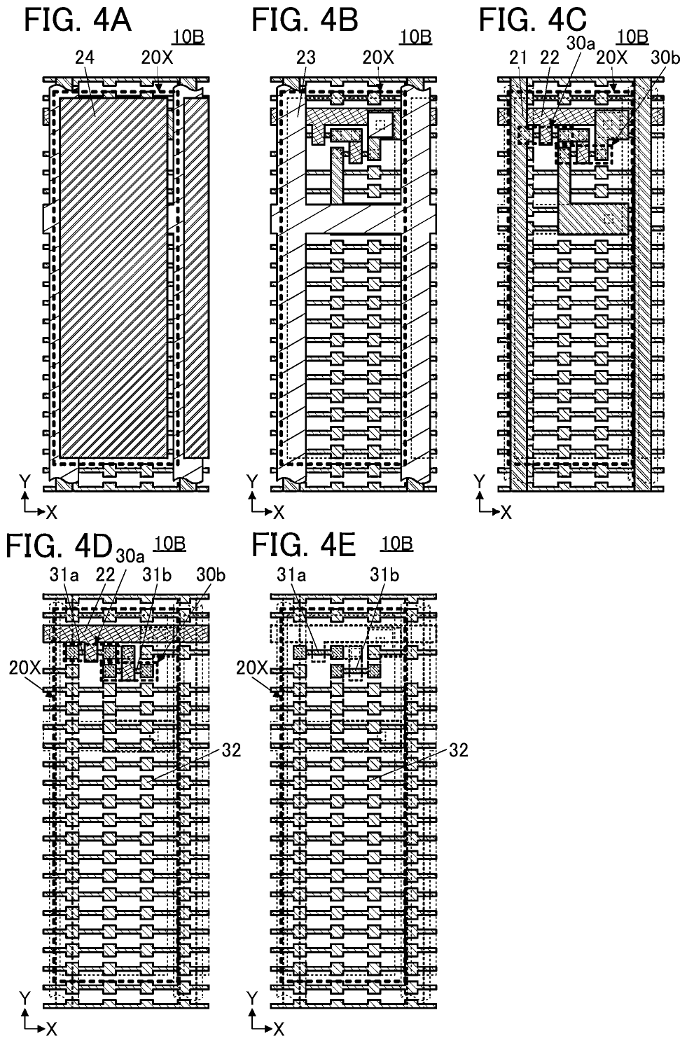

FIG. 4A to FIG. 4E illustrate schematic top views of the subpixel 20X included in a display apparatus 10B. The display apparatus 10B differs from the display apparatus 10A mainly in the directions of the semiconductor layer 31a, the semiconductor layer 31b, and the dummy layers 32.

The semiconductor layer 31a and the semiconductor layer 31b are each placed so that current flows in the X direction, i.e., a direction parallel to a direction in which the wiring 22 extends. In other words, the transistor 30a and the transistor 30b are each placed so that the channel length direction thereof is parallel to the X direction and the channel width direction thereof is parallel to the Y direction.

In addition, the dummy layers 32 are placed so that the longitudinal direction thereof is parallel to the X direction. The dummy layer 32 is placed across a plurality of pixels arranged in the X direction.

Note that the display apparatus 10B is an example where the dummy layer 32 includes a portion overlapping with the wiring 21.

### Structure Example 2-3

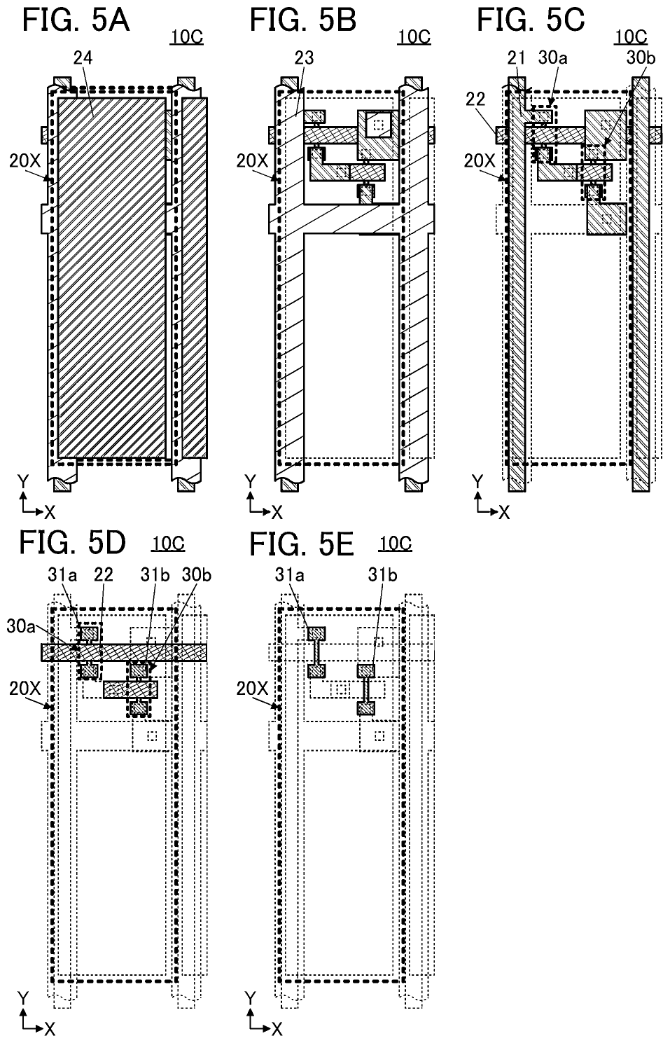

FIG. 5A to FIG. 5E illustrate schematic top views of the subpixel 20X included in a display apparatus 10C. The display apparatus 10C differs from the display apparatus 10A mainly in that the dummy layers 32 are not included.

Note that the display apparatus 10B illustrated in Structure Example 2-2 may have a structure including no dummy layer 32, like the display apparatus 10C.

### Structure Example 3

A structure example of a display apparatus that is different from Structure Example 2 is described below. Note that portions similar to those described above are denoted by the same reference numerals and the description thereof is omitted in some cases.

### [Example of Pixel Arrangement]

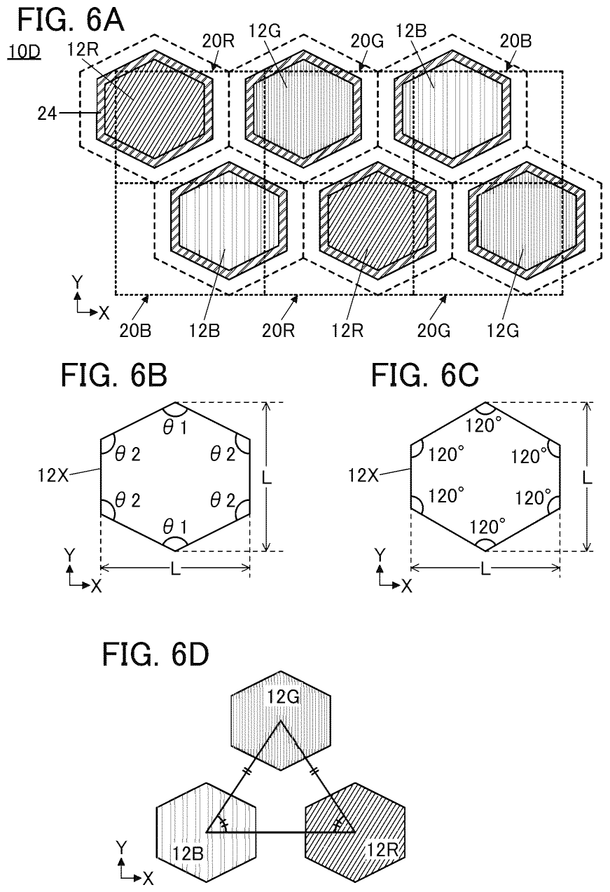

FIG. 6A illustrates a schematic top view of part of a display apparatus 10D. FIG. 6A illustrates an example of a method for arranging six light-emitting elements. A structure illustrated in FIG. 6A is one unit, and units are arranged in the X direction and the Y direction repeatedly in a pixel portion included in the display apparatus 10D.

FIG. 6A illustrates six pixel electrodes 24, two light-emitting elements 12R, two light-emitting elements 12G, and two light-emitting elements 12B. In addition, regions where two subpixels 20R, two subpixels 20G, and two subpixels 20B are provided are shown by dashed lines.

Each of the light-emitting elements is placed inside one of the closest-packed hexagonal regions. Focusing on one of the light-emitting elements, the light-emitting element is placed to be surrounded by six light-emitting elements. In addition, light-emitting elements of the same color are provided not to be adjacent to each other. For example, focusing on the light-emitting element 12R, the light-emitting element 12R is surrounded by three light-emitting elements 12G and three light-emitting elements 12B that are alternately placed.

In addition, it is preferable that a light-emitting region of the light-emitting element also have a hexagonal top surface shape. Furthermore, it is preferable that the pixel electrode 24 also have a hexagonal top surface shape.

FIG. 6B and FIG. 6C each illustrate an example of the top surface shape of the light-emitting region of the light-emitting element 12.

In a light-emitting element 12X illustrated in each of FIG. 6B and FIG. 6C, a length between a pair of vertices positioned in the Y direction and a distance between a pair of sides extending in the Y direction are equal to each other and are each a length L. Therefore, the alignment pitch of pixels in the X direction can be made equal to that in the Y direction. Note that in the case of the closest-packed arrangement of regular hexagons, it is difficult to make the arrangement pitches in the X direction and the Y direction equal to each other; therefore, it is preferable not to use regular hexagons.

In addition, in the light-emitting element 12X illustrated in FIG. 6B, interior angles (angles θ1) of the pair of vertices positioned in the Y direction are equal to each other, and interior angles (angles θ2) of the other four vertices are equal to each other. Here, the angle θ1 is an angle greater than 120°, and the angle θ2 is an angle less than 120°.

In addition, in the light-emitting element 12X illustrated in FIG. 6C, all the six interior angles are each 120°. Furthermore, the length of each of the pair of sides extending in the Y direction is shorter than that of each of the other sides.

Note that actually, the top surface shape of the light-emitting element 12X is often rounded at the corners of vertices; therefore, the above angles and lengths of the sides are applied to a hexagonal figure analogous to the light-emitting element 12X.

In addition, although the shape of the light-emitting element 12X has been described here, it is preferable that the pixel electrode also have a similar shape. In that case, the light-emitting region can be provided to overlap with the pixel electrode and be positioned inside the pixel electrode in a plan view.

FIG. 6D illustrates the positions of three adjacent light-emitting elements (the light-emitting element 12R, the light-emitting element 12G, and the light-emitting element 12B). As illustrated in FIG. 6D, the three light-emitting elements are preferably positioned to be on vertices of an isosceles triangle. In that case, in the isosceles triangle, the angle of a vertex positioned in the Y direction is preferably greater than each of the angles of the vertices at both ends of a side parallel to the X direction.

### Structure Example 3-1

Next, a more specific structure example of a pixel is described.

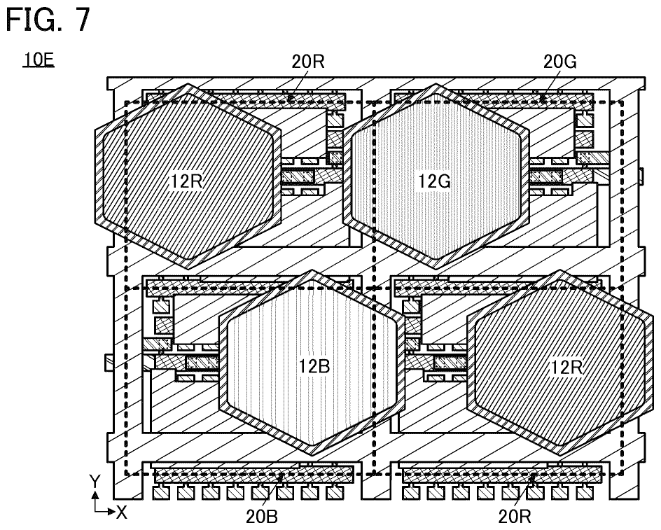

FIG. 7 illustrates a schematic top view of a display apparatus 10E. An area including 2×2 subpixels is illustrated in FIG. 7. The subpixel 20G, the subpixel 20B, and the two subpixels 20R are illustrated in FIG. 7.

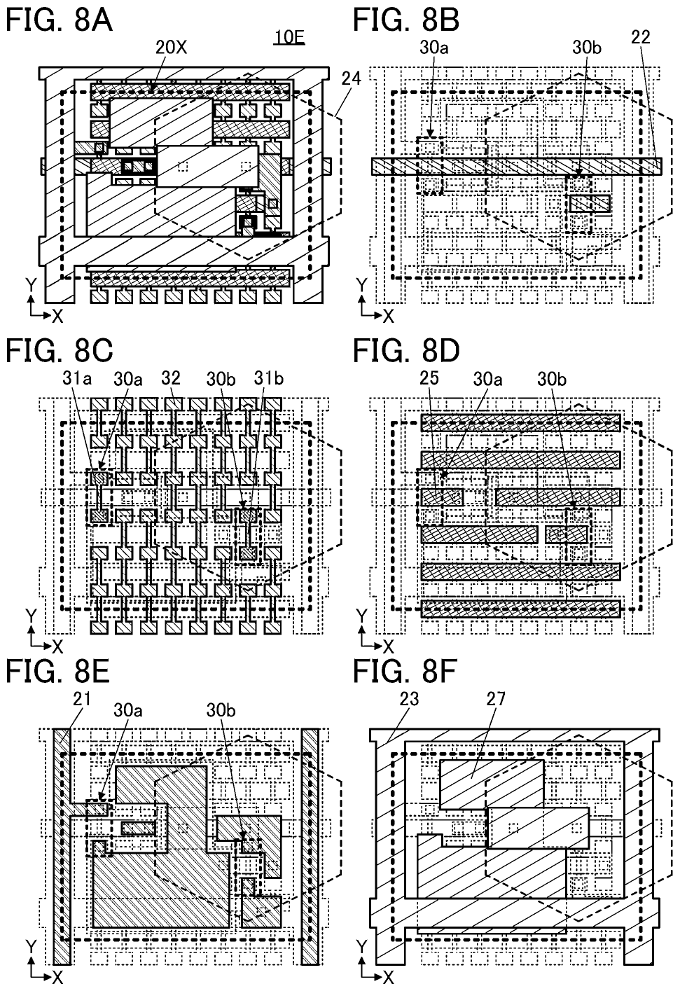

FIG. 8A illustrates a schematic top view of one subpixel 20X included in the display apparatus 10E. The subpixel 20X can be employed as the subpixel 20R, the subpixel 20G, or the subpixel 20B in FIG. 7. Note that in FIG. 8A, the pixel electrode 24 is represented only as an outline by a dashed line.

FIG. 8B to FIG. 8F each illustrate the layout of layers that constitute the subpixel 20X. FIG. 8B illustrates a layer positioned closest to the formation surface side, and FIG. 8F illustrates two layers closest to the pixel electrode 24 side.

FIG. 8B illustrates a layer including the wiring 22 and a conductive layer obtained by processing the same conductive film as the wiring 22. Part of them functions as one of gate electrodes (also referred to as a bottom gate electrode, a first gate electrode, or the like) of the transistor 30a or the transistor 30b.

FIG. 8C illustrates a layer including the semiconductor layer 31a, the semiconductor layer 31b, and the plurality of dummy layers 32. Although the case where the channel length direction is parallel to the Y direction is shown here, the layer may be laid out so that the channel length direction is parallel to the X direction in a manner similar to that in Structure Example 2-2.

FIG. 8D illustrates a layer including a plurality of conductive layers 25. Part of the conductive layer 25 functions as the other gate electrode (also referred to as a top gate electrode, a second gate electrode, or the like) of the transistor 30a or the transistor 30b. In addition, the conductive layer 25 that is electrically floating may be included as a dummy layer. By providing the dummy layer, variation in the processing shape of the conductive layer 25 or the like can be reduced.

FIG. 8E illustrates a layer including the wiring 21 and a plurality of conductive layers obtained by processing the same conductive film as the wiring 21. Part of the plurality of conductive layers illustrated in FIG. 8E functions as one of a source electrode and a drain electrode of the transistor 30a or the transistor 30b. In addition, part of the plurality of conductive layers illustrated in FIG. 8E functions as one electrode of a capacitor.

FIG. 8F illustrates a layer including a conductive layer 27 and a layer that includes the wiring 23 positioned above the layer including the conductive layer 27 and a conductive film obtained by processing the same conductive film as the wiring 23. The pixel electrode 24 is provided above the wiring 23. Part of the conductive layer 27 functions as the other electrode of the capacitor. In addition, part of the conductive layer obtained by processing the same conductive film as the wiring 23 functions as a relay wiring that electrically connects the pixel electrode 24 and the transistor 30b.

### Structure Example 3-2

The structures of the subpixel including two transistors have been described above, and a structure example of a subpixel including four transistors is described below. Note that in the description below, the above description is referred to for portions similar to those in Structure Example 3-1 and the like, and the description thereof is omitted in some cases.

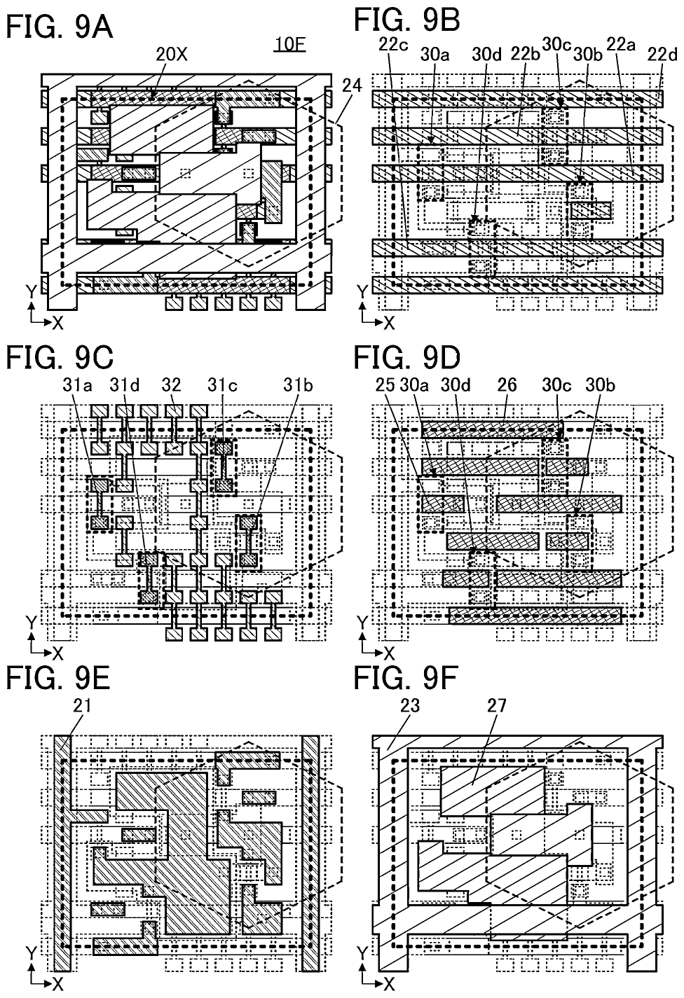

FIG. 9A to FIG. 9F illustrate structure examples of a display apparatus 10F including the subpixel 20X with four transistors.

The subpixel 20X includes the transistor 30a, the transistor 30b, a transistor 30c, and a transistor 30d.

As illustrated in FIG. 9B, three gate lines (a wiring 22a, a wiring 22b, and a wiring 22c) and a wiring 22d supplied with a constant potential are provided. Part of the wiring 22a functions as one of gate electrodes of the transistor 30a. Part of the wiring 22b functions as one of gate electrodes of the transistor 30c. Part of the wiring 22c functions as one of gate electrodes of the transistor 30d.

As illustrated in FIG. 9C, a semiconductor layer 31c included in the transistor 30c and a semiconductor layer 31d included in the transistor 30d are placed so that current flows in the Y direction in a manner similar to that of the semiconductor layer 31a and the semiconductor layer 31b. In addition, the dummy layer 32 is placed in a gap between the semiconductor layers so that the longitudinal direction thereof is parallel to the Y direction. Note that although the case where the channel length direction is parallel to the Y direction is shown here, the semiconductor layer 31c included in the transistor 30c and the semiconductor layer 31d included in the transistor 30d may be laid out so that the channel length direction is parallel to the X direction in a manner similar to that in Structure Example 2-2.

As illustrated in FIG. 9B to FIG. 9D, each of the transistor 30a, the transistor 30b, the transistor 30c, and the transistor 30d is a transistor including a pair of gate electrodes. Note that one or more of the four transistors may be transistors each including only one gate (single-gate transistors) and the other transistors may be transistors each including a pair of gates (dual-gate transistors).

### [Pixel Circuit]

A structure example and a driving method example of a pixel circuit that can be employed for the display apparatus according to one embodiment of the present invention are described below.

### [Structure Example of Pixel Circuit]

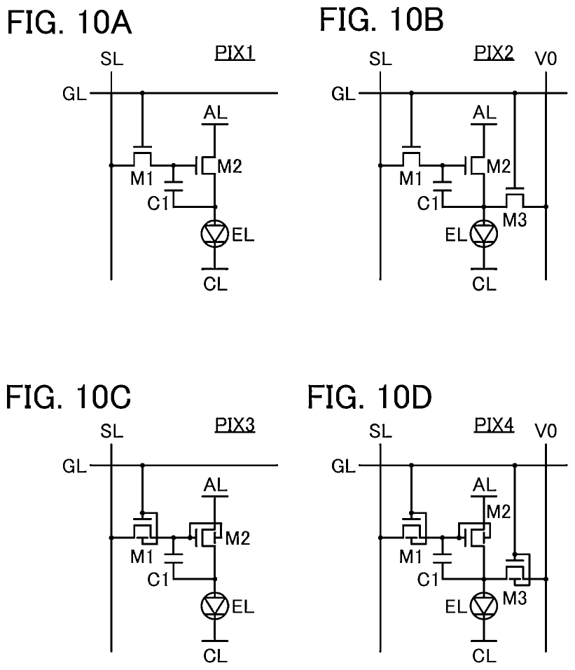

A pixel circuit PIX1 illustrated in FIG. 10A includes a transistor M1, a transistor M2, a capacitor C1, and a light-emitting element EL. In addition, a wiring SL, a wiring GL, a wiring AL, and a wiring CL are electrically connected to the pixel circuit PIX1.

A gate of the transistor M1 is electrically connected to the wiring GL, one of a source and a drain of the transistor M1 is electrically connected to the wiring SL, and the other of the source and the drain of the transistor M1 is electrically connected to a gate of the transistor M2 and one electrode of the capacitor C1. One of a source and a drain of the transistor M2 is electrically connected to the wiring AL, and the other of the source and the drain of the transistor M2 is electrically connected to an anode of the light-emitting element EL. The other electrode of the capacitor C1 is electrically connected to the anode of the light-emitting element EL. A cathode of the light-emitting element EL is electrically connected to the wiring CL.

The transistor M1 can be also referred to as a selection transistor and functions as a switch for controlling selection/non-selection of the pixel. The transistor M2 can be also referred to as a drive transistor and has a function of controlling current flowing to the light-emitting element EL. The capacitor C1 functions as a storage capacitor and has a function of retaining a gate potential of the transistor M2. A capacitor such as a MIM capacitor may be employed as the capacitor C1; alternatively, capacitance between wirings, gate capacitance of the transistor, or the like may be used as the capacitor C1.

A source signal is supplied to the wiring SL. Agate signal is supplied to the wiring GL. Each of the wiring AL and the wiring CL is supplied with a constant potential. The anode side of the light-emitting element EL can be set to a high potential, and the cathode side can be set to a lower potential than the anode side.

A pixel circuit PIX2 illustrated in FIG. 10B has a structure where a transistor M3 is added to the pixel circuit PIX1. In addition, a wiring V0 is electrically connected to the pixel circuit PIX2.

A gate of the transistor M3 is electrically connected to the wiring GL, one of a source and a drain of the transistor M3 is electrically connected to the anode of the light-emitting element EL, and the other of the source and the drain of the transistor M3 is electrically connected to the wiring V0.

A constant potential is applied to the wiring V0 when data is written to the pixel circuit PIX2. Thus, variation in the gate-source voltage of the transistor M2 can be suppressed.

A pixel circuit PIX3 illustrated in FIG. 10C is an example of the case where transistors each including a pair of gates electrically connected to each other are employed as the transistor M1 and the transistor M2 of the pixel circuit PIX1. In addition, a pixel circuit PIX4 illustrated in FIG. 10D is an example of the case where such transistors are employed in the pixel circuit PIX2. Thus, current that can flow to the transistors can be increased. Note that although a transistor including a pair of gates electrically connected to each other is employed as each of all the transistors here, one embodiment of the present invention is not limited thereto. Alternatively, a transistor that includes a pair of gates electrically connected to different wirings may be employed. For example, when a transistor whose one of gates is electrically connected to a source is used, reliability can be increased.

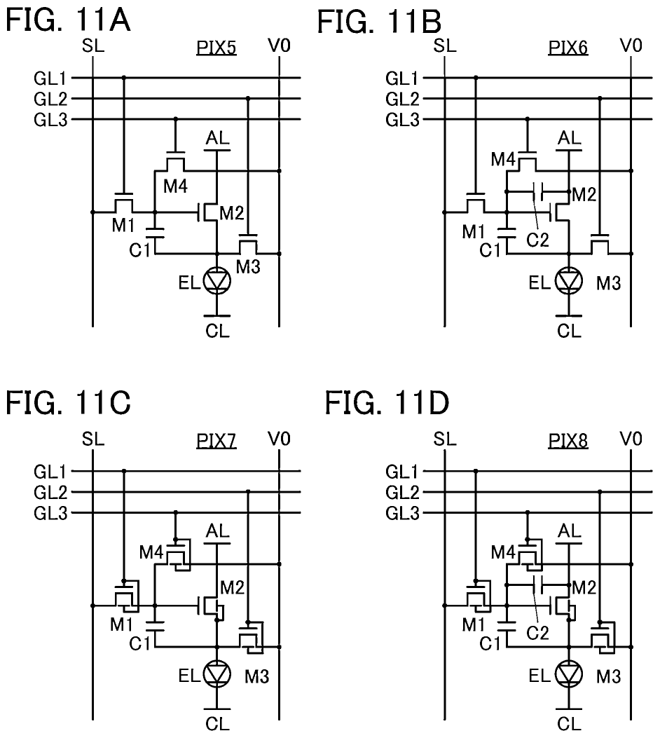

A pixel circuit PIX5 illustrated in FIG. 11A has a structure where a transistor M4 is added to the pixel circuit PIX2. In addition, three wirings functioning as gate lines (a wiring GL1, a wiring GL2, and a wiring GL3) are electrically connected to the pixel circuit PIX5.

A gate of the transistor M4 is electrically connected to the wiring GL3, one of a source and a drain of the transistor M4 is electrically connected to a gate of the transistor M2, and the other of the source and the drain of the transistor M4 is electrically connected to the wiring V0. In addition, the gate of the transistor M1 is electrically connected to the wiring GL1, and the gate of the transistor M3 is electrically connected to the wiring GL2.

When the transistor M3 and the transistor M4 are brought into conduction at the same time, the source and the gate of the transistor M2 have the same potential, so that the transistor M2 can be brought out of conduction. Thus, current flowing to the light-emitting element EL can be forcibly blocked. Such a pixel circuit is suitable for the case of using a display method in which a display period and a non-lighting period are alternately provided.

A pixel circuit PIX6 illustrated in FIG. 11B is an example of the case where a capacitor C2 is added to the pixel circuit PIX5. The capacitor C2 functions as a storage capacitor.

Each of a pixel circuit PIX7 illustrated in FIG. 11C and a pixel circuit PIX8 illustrated in FIG. 11D is an example of the case where a transistor including a pair of gates is employed in the pixel circuit PIX5 or the pixel circuit PIX6. A transistor including a pair of gates electrically connected to each other is employed as each of the transistor M1, the transistor M3, and the transistor M4, and a transistor whose source is electrically connected to one of gates is employed as the transistor M2.

### [Driving Method Example]

An example of a method for driving a display apparatus in which the pixel circuit PIX5 is employed is described below. Note that a similar driving method can be applied to the pixel circuits PIX6, PIX7, and PIX8.

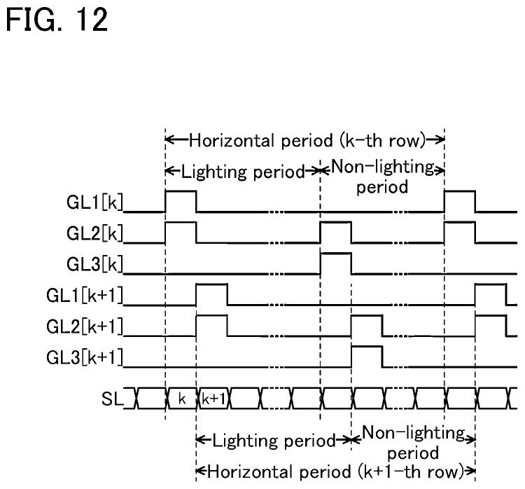

FIG. 12 shows a timing chart of a method for driving the display apparatus in which the pixel circuit PIX5 is employed. Changes in potentials of a wiring GL1[k], a wiring GL2[k], and a wiring GL3[k] that are gate lines of a k-th row and a wiring GL1[k+1], a wiring GL2[k+1], and a wiring GL3[k+1] that are gate lines of a k+1-th row are shown here. FIG. 12 also shows the timing of a signal supplied to the wiring SL functioning as a source line.

Here, an example of a driving method in which one horizontal period is divided into a lighting period and a non-lighting period is shown. In addition, a horizontal period of the k-th row is shifted from a horizontal period of the k+1-th row by a selection period of the gate line.

In a lighting period of the k-th row, first, a high-level potential is applied to the wiring GL1[k] and the wiring GL2[k], and a source signal is supplied to the wiring SL. Thus, the transistor M1 and the transistor M3 are brought into conduction, so that a potential corresponding to the source signal is written from the wiring SL to the gate of the transistor M2. After that, a low-level potential is applied to the wiring GL1[k] and the wiring GL2[k], so that the transistor M1 and the transistor M3 are brought out of conduction and the gate potential of the transistor M2 is retained.

Subsequently, the operation moves to a lighting period of the k+1-th row, and data is written by an operation similar to that described above.

Next, the non-lighting period is described. In the non-lighting period of the k-th row, a high-level potential is applied to the wiring GL2[k] and the wiring GL3[k]. Accordingly, the transistor M3 and the transistor M4 are brought into conduction, and the same potential is applied to the source and the gate of the transistor M2, so that almost no current flows to the transistor M2. Therefore, the light from the light-emitting element EL is put out. The light of all the subpixels positioned in the k-th row is put out. The subpixels of the k-th row remain in a non-lighting state until the next lighting period.

Subsequently, the operation moves to the non-lighting period of the k+1-th row, and the light of all the subpixels of the k+1-th row is put out in a manner similar to that described above.

Such a driving method in which a non-lighting period is provided in one horizontal period instead of constantly lighting on in one horizontal period can be also referred to as duty driving. With duty driving, an afterimage phenomenon can be reduced at the time of displaying a moving image; therefore, a display apparatus with high performance in displaying a moving image can be achieved. Particularly in a VR device and the like, a reduction in an afterimage can reduce what is called VR sickness.

In the duty driving, the proportion of the lighting period in one horizontal period can be called a duty ratio. For example, a duty ratio of 50% means that the lighting period and the non-lighting period have the same length. Note that the duty ratio can be freely set and can be adjusted as appropriate in a range higher than 0% and lower than or equal to 100%, for example.

The above is the description of the driving method example.

### [Example of Cross-sectional Structure]

Next, cross-sectional structure examples of the display apparatus according to one embodiment of the present invention are described.

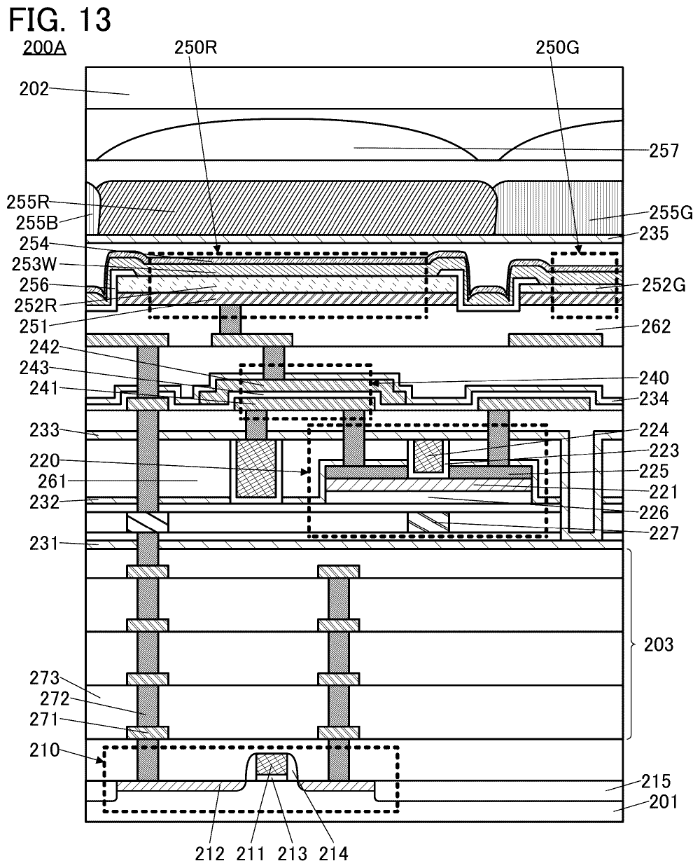

FIG. 13 is a schematic cross-sectional view of a display apparatus 200A. The display apparatus 200A includes a light-emitting element 250R, a light-emitting element 250G, a transistor 210, a transistor 220, a capacitor 240, and the like between a substrate 201 and a substrate 202.

The transistor 210 is a transistor whose channel formation region is formed in the substrate 201. As the substrate 201, a semiconductor substrate such as a single crystal silicon substrate can be used, for example. The transistor 210 includes part of the substrate 201, a conductive layer 211, low-resistance regions 212, an insulating layer 213, insulating layers 214, and the like. The conductive layer 211 functions as a gate electrode. The insulating layer 213 is positioned between the substrate 201 and the conductive layer 211 and functions as a gate insulating layer. The low-resistance region 212 is a region where the substrate 201 is doped with an impurity, and functions as one of a source and a drain. The insulating layer 214 is provided to cover a side surface of the conductive layer 211.

In addition, an element isolation layer 215 is provided between two adjacent transistors 210 to be embedded in the substrate 201.

A wiring layer 203 is provided between the transistor 210 and the transistor 220. The wiring layer 203 has a structure where layers each including one or more wirings are stacked. Each of the layers includes a conductive layer 271, and an interlayer insulating layer 273 is provided between two layers. Furthermore, the conductive layers 271 of different layers are electrically connected to one another with plugs 272 provided in the interlayer insulating layers 273.

The transistor 220 is provided over the wiring layer 203. The transistor 220 is a transistor in which a metal oxide (also referred to as an oxide semiconductor) is employed in a semiconductor layer where a channel is formed.

The transistor 220 includes a semiconductor layer 221, an insulating layer 223, a conductive layer 224, a pair of conductive layers 225, an insulating layer 226, a conductive layer 227, and the like.

An insulating layer 231 is provided over the wiring layer 203. The insulating layer 231 functions as a barrier layer that prevents diffusion of impurities such as water or hydrogen from the wiring layer 203 side into the transistor 220 and release of oxygen from the semiconductor layer 221 to the wiring layer 203 side. As the insulating layer 231, for example, a film in which hydrogen or oxygen is less likely to diffuse than in a silicon oxide film, such as an aluminum oxide film, a hafnium oxide film, and a silicon nitride film, can be used.

The conductive layer 227 is provided over the insulating layer 231, and the insulating layer 226 is provided to cover the conductive layer 227. The conductive layer 227 functions as a first gate electrode of the transistor 220, and part of the insulating layer 226 functions as a first gate insulating layer. For at least in a portion in contact with the semiconductor layer 221 in the insulating layer 226, an oxide insulating film such as a silicon oxide film is preferably used.

The semiconductor layer 221 is provided over the insulating layer 226. The semiconductor layer 221 preferably includes a film of a metal oxide having semiconductor characteristics (also referred to as an oxide semiconductor).

In the case where the semiconductor layer 221 is an In-M-Zn oxide, examples of the atomic ratio of metal elements of a sputtering target used for depositing the In-M-Zn oxide include In:M:Zn=1:1:1, In:M:Zn=1:1:1.2, In:M:Zn=1:3:2, In:M:Zn=1:3:4, In:M:Zn=1:3:6, In:M:Zn=2:2:1, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, and In:M:Zn=5:2:5.

In addition, a target containing a polycrystalline oxide is preferably used as the sputtering target because formation of the semiconductor layer 221 having crystallinity is facilitated. Note that the atomic ratio in the semiconductor layer 221 to be deposited varies in the range of ±40% from the atomic ratio of the metal elements contained in the sputtering target. For example, in the case where the composition of a sputtering target used for the semiconductor layer 221 is In:Ga:Zn=4:2:4.1 [atomic ratio], the composition of the semiconductor layer 221 to be deposited is in the neighborhood of In:Ga:Zn=4:2:3 [atomic ratio] in some cases.

Note that when the atomic ratio is described as In:Ga:Zn=4:2:3 or as being in the neighborhood thereof, the case is included in which Ga is greater than or equal to 1 and less than or equal to 3 and Zn is greater than or equal to 2 and less than or equal to 4 with In being 4. In addition, when the atomic ratio is described as In:Ga:Zn=5:1:6 or as being in the neighborhood thereof, the case is included in which Ga is greater than 0.1 and less than or equal to 2 and Zn is greater than or equal to 5 and less than or equal to 7 with In being 5. Furthermore, when the atomic ratio is described as In:Ga:Zn=1:1:1 or as being in the neighborhood thereof, the case is included in which Ga is greater than 0.1 and less than or equal to 2 and Zn is greater than 0.1 and less than or equal to 2 with In being 1.

In addition, the energy gap of the semiconductor layer 221 is greater than or equal to 2 eV, preferably greater than or equal to 2.5 eV. With the use of such a metal oxide having a wider energy gap than silicon, the off-state current of the transistor can be reduced.

Furthermore, the semiconductor layer 221 preferably has a non-single-crystal structure. Examples of the non-single-crystal structure include a CAAC structure to be described later, a polycrystalline structure, a microcrystalline structure, and an amorphous structure. Among the non-single-crystal structures, the amorphous structure has the highest density of defect states, whereas the CAAC structure has the lowest density of defect states.

A CAAC (c-axis aligned crystal) will be described below. A CAAC refers to an example of a crystal structure.

The CAAC structure is a crystal structure of a thin film or the like that has a plurality of nanocrystals (crystal regions having a maximum diameter of less than 10 nm), characterized in that the nanocrystals each have c-axis alignment in a particular direction, the nanocrystals each have neither a-axis alignment nor b-axis alignment, and the nanocrystals have continuous crystal connection in the a-axis and b-axis directions without forming a grain boundary. In particular, a thin film having the CAAC structure is characterized in that the c-axes of nanocrystals are likely to be aligned in a film thickness direction, a normal direction of a surface where the thin film is formed, or a normal direction of a surface of the thin film.

A CAAC-OS (Oxide Semiconductor) is an oxide semiconductor with high crystallinity. Meanwhile, in the CAAC-OS, it can be said that a reduction in electron mobility due to the crystal grain boundary is less likely to occur because a clear crystal grain boundary cannot be observed. Furthermore, the mixing of impurities, formation of defects, or the like might decrease the crystallinity of the oxide semiconductor; thus, it can also be said that the CAAC-OS is an oxide semiconductor having small amounts of impurities and defects (oxygen vacancies or the like). Thus, an oxide semiconductor including a CAAC-OS is physically stable. Therefore, the oxide semiconductor including a CAAC-OS is resistant to heat and has high reliability.

Here, in crystallography, in a unit cell formed with three axes (crystal axes) of the a-axis, the b-axis, and the c-axis, a specific axis is generally taken as the c-axis in the unit cell. In particular, in the case of a crystal having a layered structure, two axes parallel to the plane direction of a layer are regarded as the a-axis and the b-axis and an axis intersecting with the layer is regarded as the c-axis in general. Typical examples of such a crystal having a layered structure include graphite, which is classified as a hexagonal system. In a unit cell of graphite, the a-axis and the b-axis are parallel to a cleavage plane and the c-axis is orthogonal to the cleavage plane. For example, an InGaZnO₄ crystal having a YbFe₂O₄ type crystal structure, which is a layered structure, can be classified as a hexagonal system, and in a unit cell thereof, the a-axis and the b-axis are parallel to the plane direction of a layer and the c-axis is orthogonal to the layer (i.e., the a-axis and the b-axis).

In an image observed with a TEM, crystal parts cannot be found clearly in an oxide semiconductor film having a microcrystalline structure (a microcrystalline oxide semiconductor film) in some cases. Inmost cases, the size of a crystal part included in the microcrystalline oxide semiconductor film is greater than or equal to 1 nm and less than or equal to 100 nm, or greater than or equal to 1 nm and less than or equal to 10 nm. In particular, an oxide semiconductor film including a nanocrystal (nc) that is a microcrystal with a size greater than or equal to 1 nm and less than or equal to 10 nm, or greater than or equal to 1 nm and less than or equal to 3 nm is referred to as an nc-OS (nanocrystalline Oxide Semiconductor) film. In addition, in an image observed with a TEM, for example, a crystal grain boundary cannot be found clearly in the nc-OS film in some cases.

In the nc-OS film, a microscopic region (e.g., a region greater than or equal to 1 nm and less than or equal to 10 nm, in particular, a region greater than or equal to 1 nm and less than or equal to 3 nm) has periodic atomic arrangement. In addition, there is no regularity of crystal orientation between different crystal parts in the nc-OS film. Hence, the orientation in the whole film is not observed. Accordingly, in some cases, the nc-OS film cannot be distinguished from an amorphous oxide semiconductor film depending on an analysis method. For example, when the nc-OS film is subjected to structural analysis by an out-of-plane method with an XRD apparatus using an X-ray having a diameter larger than the size of a crystal part, a peak that shows a crystal plane is not detected. Furthermore, a diffraction pattern like a halo pattern is observed when the nc-OS film is subjected to electron diffraction (also referred to as selected-area electron diffraction) using an electron beam with a probe diameter larger than the diameter of a crystal part (e.g., larger than or equal to 50 nm). Meanwhile, in some cases, a circular (ring-like) region with high luminance is observed when the nc-OS film is subjected to electron diffraction (also referred to as nanobeam electron diffraction) using an electron beam with a probe diameter close to or smaller than the diameter of a crystal part (e.g., larger than or equal to 1 nm and smaller than or equal to 30 nm), and spots are observed in the ring-like region.

The nc-OS film has a lower density of defect states than the amorphous oxide semiconductor film. Note that there is no regularity of crystal orientation between different crystal parts in the nc-OS film. Thus, the nc-OS film has a higher density of defect states than the CAAC-OS film. Therefore, the nc-OS film has a higher carrier density and higher electron mobility than the CAAC-OS film in some cases. Accordingly, a transistor using the nc-OS film might exhibit a high field-effect mobility.

The nc-OS film can be formed at a smaller oxygen flow rate ratio in deposition than the CAAC-OS film. The nc-OS film can be also formed at a lower substrate temperature in deposition than the CAAC-OS film. For example, the nc-OS film can be deposited at a comparatively low substrate temperature (e.g., a temperature lower than or equal to 130° C.) or without heating of the substrate and thus is suitable for the case of using a large glass substrate, a resin substrate, or the like, and productivity can be increased.

An example of a crystal structure of a metal oxide is described. A metal oxide formed by a sputtering method using an In—Ga—Zn oxide target (In:Ga:Zn=4:2:4.1 [atomic ratio]) at a substrate temperature higher than or equal to 100° C. and lower than or equal to 130° C. is likely to have either an nc (nano crystal) structure or the CAAC structure, or a structure in which both structures are mixed. In contrast, a metal oxide formed at a substrate temperature set at room temperature (R.T.) is likely to have the nc structure. Note that room temperature (R.T.) here also includes a temperature when a substrate is not heated intentionally.

The pair of conductive layers 225 is provided on and in contact with the semiconductor layer 221, and functions as a source electrode and a drain electrode.

In addition, an insulating layer 232 is provided to cover top surfaces and side surfaces of the pair of conductive layers 225, side surfaces of the semiconductor layer 221, and the like, and an insulating layer 261 is provided over the insulating layer 232. The insulating layer 232 functions as a barrier layer that prevents diffusion of impurities such as water or hydrogen from the interlayer insulating layer or the like into the semiconductor layer 221 and release of oxygen from the semiconductor layer 221. For the insulating layer 232, an insulating film similar to the insulating layer 231 can be used.

An opening reaching the semiconductor layer 221 is provided in the insulating layer 232 and the insulating layer 261. The insulating layer 223 that is in contact with the side surfaces of the insulating layer 261, the insulating layer 232, and the conductive layer 225 and the top surface of the semiconductor layer 221, and the conductive layer 224 over the insulating layer 223 are embedded in the opening. The conductive layer 224 functions as a second gate electrode, and the insulating layer 223 functions as a second gate insulating layer.

The top surface of the conductive layer 224, the top surface of the insulating layer 223, and the top surface of the insulating layer 261 are subjected to planarization treatment so that they are substantially level with each other, and an insulating layer 233 is provided to cover these layers. In addition, an opening portion is provided in a stacked-layer structure between the insulating layer 233 and the insulating layer 231, and part of the insulating layer 233 is provided in contact with the insulating layer 231 in the opening portion. The insulating layer 261 functions as an interlayer insulating layer. Furthermore, the insulating layer 233 functions as a barrier layer that prevents diffusion of impurities such as water or hydrogen from layers above. For the insulating layer 233, an insulating film similar to the insulating layer 231 or the like can be used.

The capacitor 240 is provided over the insulating layer 233.

The capacitor 240 includes a conductive layer 241, a conductive layer 242, and an insulating layer 243 positioned therebetween. The conductive layer 241 functions as one electrode of the capacitor 240, the conductive layer 242 functions as the other electrode of the capacitor 240, and the insulating layer 243 functions as a dielectric of the capacitor 240.

An insulating layer 234 is provided to cover the capacitor 240. For the insulating layer 234, an insulating film similar to the insulating layer 231 can be used. An insulating layer 262 is provided over the insulating layer 231 with an interlayer insulating layer and a wiring therebetween, and the light-emitting element 250R and the light-emitting element 250G are provided over the insulating layer 262.

The light-emitting element 250R includes a conductive layer 251, a conductive layer 252R, an EL layer 253W, a conductive layer 254, and the like.

The conductive layer 251 has a property of reflecting visible light, and the conductive layer 252R has a property of transmitting visible light. The conductive layer 254 has a property of reflecting and transmitting visible light. The conductive layer 252R functions as an optical adjustment layer for adjusting an optical path length between the conductive layer 251 and the conductive layer 254. The thickness of the optical adjustment layer can differ between the light-emitting elements of different emission colors. The thickness of the conductive layer 252R included in the light-emitting element 250R is different from the thickness of a conductive layer 252G included in the light-emitting element 250G.

An insulating layer 256 is provided to cover an end portion of the conductive layer 252R and an end portion of the conductive layer 252G.

The EL layer 253W and the conductive layer 254 are provided across a plurality of pixels to be shared by the plurality of pixels. The EL layer 253W includes a plurality of light-emitting layers to emit white light.

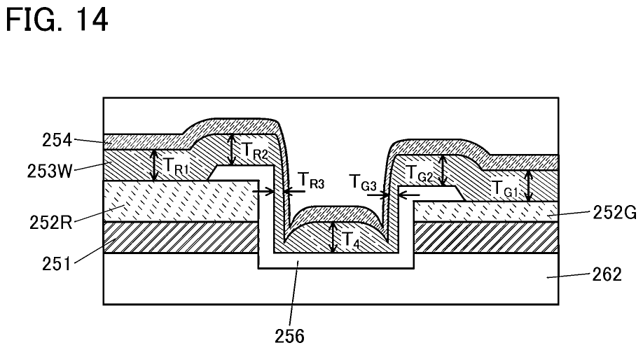

FIG. 14 illustrates an enlarged view of part of the conductive layer 252R, part of the conductive layer 252G, and a region therebetween.

A stack of the conductive layer 251 and the conductive layer 252R functions as a pixel electrode. The conductive layer 251 and the conductive layer 252R are processed so that their side surfaces are substantially perpendicular to a substrate surface or a top surface of the conductive layer 252R. Similarly, a stack of the conductive layer 251 and the conductive layer 252G are processed so that their side surfaces are substantially perpendicular to the substrate surface or a top surface of the conductive layer 252G. Note that either the conductive layer 251 or the conductive layer 252R (or the conductive layer 252G) is processed so that its side surface is substantially perpendicular to the substrate surface or the top surface of the conductive layer 252R (or the conductive layer 252G).

The insulating layer 256 is provided to cover part of the top surface and side surface of the conductive layer 252R, side surfaces of the two conductive layers 251, and part of the top surface and side surface of the conductive layer 252G. The insulating layer 256 has a concave top surface shape in a region between the conductive layer 252R and the conductive layer 252G. The EL layer 253W is provided to cover the conductive layer 252R, the insulating layer 256, and the conductive layer 252G, and includes a portion in contact with the top surface of the conductive layer 252R, a portion in contact with the top surface of the conductive layer 252G, and a portion in contact with the insulating layer 256.

Specifically, a surface of the insulating layer 256 includes part in contact with the EL layer 253W at greater than or equal to 70° and less than or equal to 120°, preferably greater than or equal to 750 and less than or equal to 115°, further preferably greater than or equal to 800 and less than or equal to 110° with respect to the substrate surface or the top surface of the conductive layer 252R or the conductive layer 252G. By forming the EL layer 253W over the insulating layer 256 having such a shape, a thin portion can be formed in a self-aligning manner. Alternatively, the EL layer 253W can be divided in a self-aligning manner. FIG. 14 illustrates the case in which one EL layer 253W is used between adjacent light-emitting elements.

The thickness of a portion of the EL layer 253W that is in contact with the top surface of the conductive layer 252R is referred to as thickness T_{R1}, the thickness of a portion of the EL layer 253W that is over the insulating layer 256 and overlaps with the conductive layer 252R is referred to as thickness T_{R2}, and the thickness of a portion of the EL layer 253W on the conductive layer 252R side that is in contact with the surface of the insulating layer 256 substantially perpendicular to the top surface of the conductive layer 252R is referred to as thickness T_{R3}. Similarly, the thickness of a portion of the EL layer 253W that is in contact with the top surface of the conductive layer 252G is referred to as thickness T_{G1}, the thickness of a portion of the EL layer 253W that is over the insulating layer 256 and overlaps with the conductive layer 252G is referred to as thickness T_{G2}, and the thickness of a portion of the EL layer 253W on the conductive layer 252G side that is in contact with the surface of the EL layer 253W substantially perpendicular to the top surface of the conductive layer 252G is referred to as thickness T_{G3}. In addition, the thickness of a portion in contact with a portion where a top surface of the insulating layer 256 is flat is referred to as thickness T₄.

Note that the thickness described here means not thickness in a direction perpendicular to a certain reference surface such as a substrate surface but thickness in a normal direction with respect to a formation surface. Therefore, in the case where the formation surface has unevenness, a direction for specifying the thickness varies from place to place.

The thickness T_{R1}, the thickness T_{R2}, the thickness T_{G1}, the thickness T_{G2}, and the thickness T₄ are substantially equal to each other. In contrast, each of the thickness T_{R3} and the thickness T_{G3} is less than each of the thickness T_{R1}, the thickness T_{R2}, the thickness T_{G1}, the thickness T_{G2}, and the thickness T₄. Specifically, each of the thickness T_{R3} and the thickness T_{G3} is half (50%) or less, preferably 40% or less, further preferably 30% or less of the thickness T_{R1}, the thickness T_{R2}, the thickness T_{G1}, the thickness T_{G2}, or the thickness T₄ and greater than 0% of the thickness T_{R1}, the thickness T_{R2}, the thickness T_{G1}, the thickness T_{G2}, or the thickness T₄.

When a region where the thickness of the EL layer 253W is small is formed between adjacent light-emitting elements in this manner, leakage current flowing through the EL layer 253W can be reduced and unintended light emission can be suppressed.

In addition, FIG. 14 illustrates an example where a region of the insulating layer 262 that is not covered with the conductive layer 251 is cut at the time of etching the conductive layer 251 or the like and is reduced in thickness. Specifically, a bottom surface of the insulating layer 256 is positioned below a bottom surface of the conductive layer 251. Roughness of a step between the adjacent light-emitting elements can be made large by performing etching part of the insulating layer 262 in this manner; therefore, formation of the region where the thickness of the EL layer 253W is small can be effectively facilitated.

In FIG. 13, a coloring layer 255R is provided over the light-emitting element 250R with an insulating layer 235 therebetween. In addition, a coloring layer 255G is provided over the light-emitting element 250G. Furthermore, part of a coloring layer 255B is illustrated in FIG. 13.

For example, the coloring layer 255R transmits red light, the coloring layer 255G transmits green light, and the coloring layer 255B transmits blue light. This can increase the color purity of light from each light-emitting element, so that a display apparatus with higher display quality can be achieved. Furthermore, positional alignment of the light-emitting elements and the coloring layers is easier in the case where the coloring layers are formed over the insulating layer 235 than in the case where the coloring layers are formed on the substrate 202 side and then the substrate 201 and the substrate 202 are attached to each other; accordingly, a display apparatus with extremely high definition can be achieved.

A lens array 257 is provided over the coloring layer 255R and over the coloring layer 255G. Light emitted from the light-emitting element 250R is colored by the coloring layer 255R and is emitted to the outside through the lens array 257. The lens array 257 is not necessarily provided when not needed.

The display apparatus 200A includes the substrate 202 on the viewer side. The substrate 202 and the substrate 201 are attached to each other. As the substrate 202, a substrate having a light-transmitting property, such as a glass substrate, a quartz substrate, a sapphire substrate, or a plastic substrate, can be used.

With such a structure, a display apparatus with extremely high definition and high display quality can be achieved.

A structure example of a display apparatus whose structure is partly different from that of the above structure example is described below.

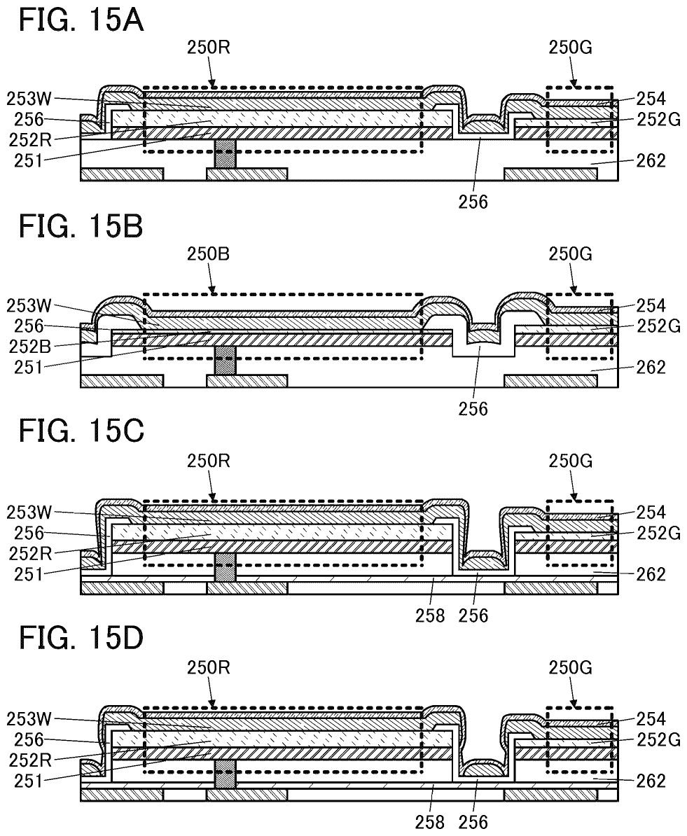

FIG. 15A to FIG. 15D each illustrate a stacked-layer structure of components from the insulating layer 262 to the conductive layer 254.

FIG. 15A differs from FIG. 14 in that a portion of the insulating layer 262 that does not overlap with the conductive layer 251 is not thinned down. Specifically, the bottom surface of the insulating layer 256 is positioned at substantially the same height as the bottom surface of the conductive layer 251. Variation in a cross-sectional shape can be suppressed without etching of the insulating layer 262; therefore, a process yield can be increased and mass productivity can be improved.

FIG. 15B is an example of the case where the insulating layer 256 is formed thick. In addition, FIG. 15B illustrates a schematic cross-sectional view of a light-emitting element 250B and the light-emitting element 250G. The light-emitting element 250B includes the conductive layer 251, a conductive layer 252B, the EL layer 253W, and the conductive layer 254. The conductive layer 252B is thinner than the conductive layer 252G.

FIG. 15B illustrates an example of the case where the insulating layer 256 is formed thicker than each of the conductive layer 252G and the conductive layer 252B.

FIG. 15C and FIG. 15D each illustrate an example of the case where an insulating layer 258 that functions as an etching stopper film is provided below the insulating layer 262. In addition, the insulating layer 262 in a region between the adjacent light-emitting elements is etched, and the bottom surface of the insulating layer 256 is in contact with the insulating layer 258. With such a structure, roughness between the adjacent light-emitting elements can be made large.

FIG. 15D illustrates an example where the EL layer 253W is divided. In that case, it is preferable that one conductive layer 254 be used between the adjacent light-emitting elements without any division of the conductive layer 254. The EL layer 253W is preferably divided between the adjacent light-emitting elements because leakage current flowing through the EL layer 253W can be completely prevented. Note that the structure illustrated in FIG. 15D corresponds to a structure where each of the thickness T_{R3} and the thickness T_{G3} in FIG. 14 is 0. In other words, the state in FIG. 15D can be also referred to as a state in which each of the thickness T_{R3} and the thickness T_{G3} is 0% of each of the thickness T_{R1}, the thickness T_{R2}, the thickness T_{G1}, the thickness T_{G2}, and the thickness T₄.

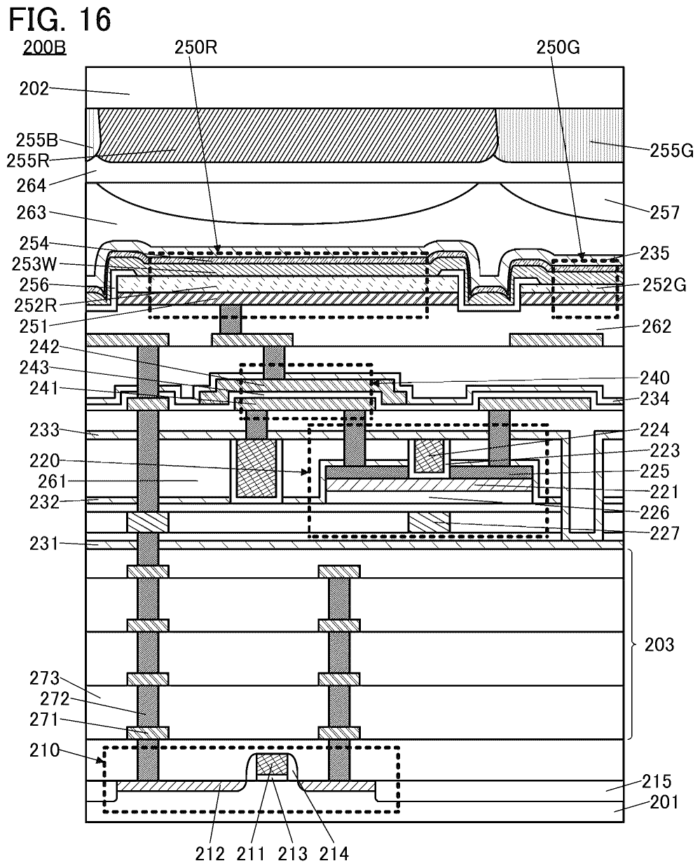

FIG. 16 illustrates a schematic cross-sectional view of a display apparatus 200B with a structure partly different from that of the display apparatus 200A.

The display apparatus 200B is an example where the coloring layer 255R, the coloring layer 255G, the coloring layer 255B, and the lens array 257 are formed on the substrate 202 side. Specifically, the coloring layer 255R, the coloring layer 255G, and the coloring layer 255B are provided on a surface of the substrate 202 on the substrate 201 side, an insulating layer 264 that functions as a planarization layer is provided to cover the coloring layer 255R, the coloring layer 255G, and the coloring layer 255B, and the lens array 257 is provided on a surface of the insulating layer 264 on the substrate 201 side. The substrate 202 and the substrate 201 are attached to each other with an adhesive layer 263.

In addition, the insulating layer 235 is provided over the conductive layer 254. In that case, the insulating layer 235 preferably has a function of preventing diffusion of moisture and the like contained in the adhesive layer 263 into the light-emitting elements. For example, the insulating layer 235 preferably includes at least an inorganic insulating film. When a metal oxide film such as an aluminum oxide film or a hafnium oxide film or an inorganic insulating film such as a silicon oxide film that is formed by an ALD (Atomic Layer Deposition) method, which has good step coverage, is particularly employed for the insulating layer 235 as an inorganic insulating film, it is possible to form the insulating layer 235 that has few pinholes and an excellent function of protecting the EL layer as well as having favorable coverage even in a region between light-emitting elements with large roughness.

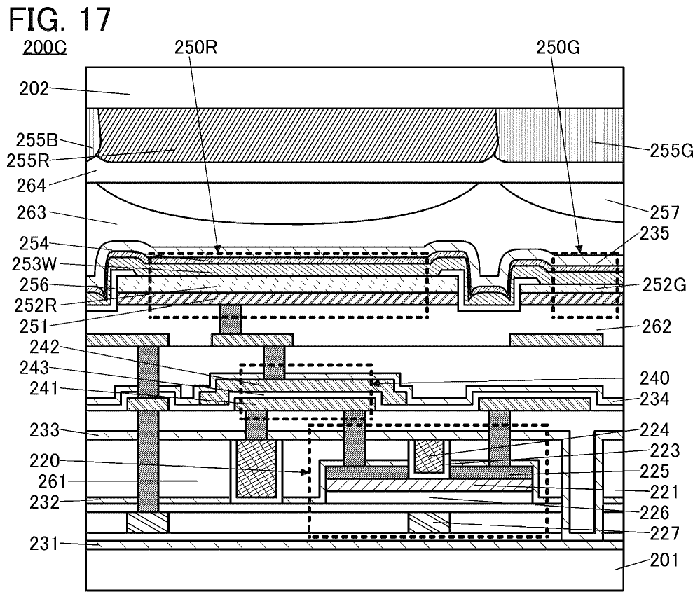

FIG. 17 is a schematic cross-sectional view of a display apparatus 200C. The display apparatus 200C differs from the display apparatus 200B mainly in that the transistor 210 is not included.

The insulating layer 231 is provided over the substrate 201, and the transistor 220 is provided over the insulating layer 231. Note that in the case where there is no possibility that impurities and the like diffuse from the substrate 201, the insulating layer 231 is not necessarily provided.

As the substrate 201, a substrate having a low coefficient of thermal expansion is preferably used. For example, it is preferable to use a single crystal semiconductor substrate of single crystal silicon, silicon carbide, or the like, a high-melting-point insulating substrate of sapphire, quartz, or the like, or the like.

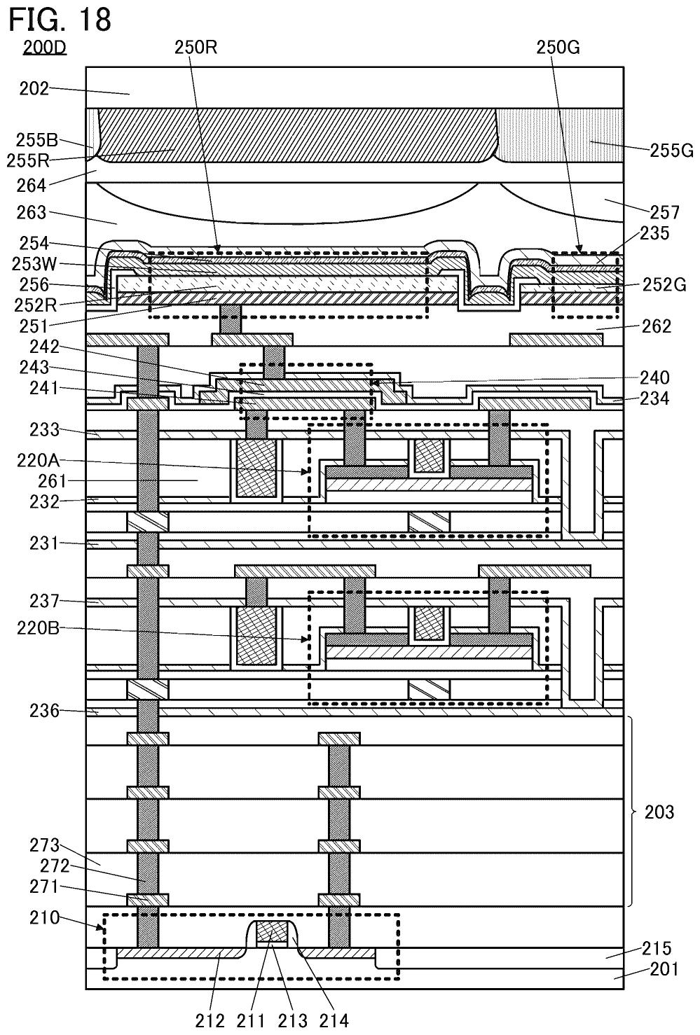

FIG. 18 is a schematic cross-sectional view of a display apparatus 200D. The display apparatus 200D differs from the display apparatus 200B mainly in the transistor stacked-layer structure.

In the display apparatus 200D, a transistor 220B and a transistor 220A are stacked over the transistor 210. The transistor 220A has a structure similar to that of the transistor 220 in the display apparatus 200B or the like. The transistor 220B is provided between an insulating layer 236 and an insulating layer 237 and has a structure similar to that of the transistor 220A. The insulating layer 236 and the insulating layer 237 each function as a barrier layer like the insulating layer 231 or the like.

When a layer including the transistor 220B is further provided between a layer including the transistor 210 and a layer including the transistor 220A in this manner, more multifunctionality can be achieved.

The above is the description of the cross-sectional structure examples.

### [Protection Circuit]

A structure example of a protection circuit that can be employed in the display apparatus is described below.

Many source lines and gate lines are arranged in a matrix in an active-matrix display apparatus. Therefore, when ESD (Electro Static Discharge) is generated in the source line or the gate line during a manufacturing process of the display apparatus, an integration process of an electronic device, or the like, a display defect is caused. Thus, a protection circuit for reducing the influence of ESD is preferably provided for the source lines and the gate lines.

In addition, an inspection circuit, terminal, electrode, or the like for examining whether pixels are correctly driven in an inspection of the display apparatus, such as a pre-shipment inspection or a sampling inspection, is provided in some cases.

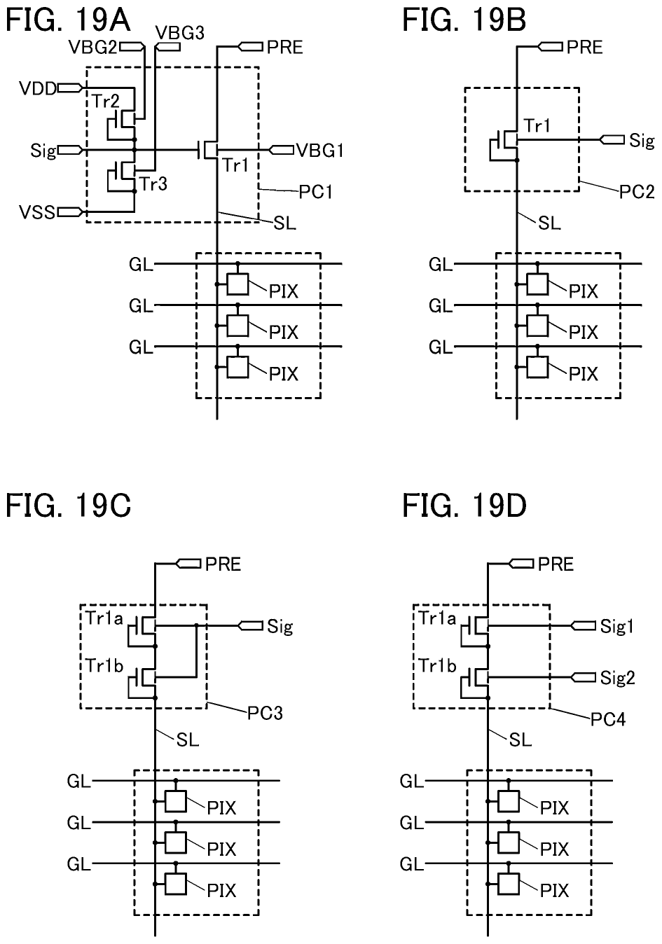

FIG. 19A illustrates an example of a circuit PC1 for inputting a potential input from a terminal PRE to a source line SL.

The circuit PC1 includes a transistor Tr1, a transistor Tr2, and a transistor Tr3. Each of the transistor Tr1, the transistor Tr2, and the transistor Tr3 is a transistor including a pair of gates. A gate positioned below a semiconductor layer is referred to as a back gate, and a gate positioned above the semiconductor layer is referred to as a top gate.

A top gate of the transistor Tr is electrically connected to a terminal Sig, a back gate of the transistor Tr is electrically connected to a terminal VBG1, one of a source and a drain of the transistor Tr is electrically connected to the source line SL, and the other of the source and the drain of the transistor Tr is electrically connected to the terminal PRE.

The terminal Sig is supplied with a signal for controlling the transistor Tr1. A bias potential is applied to the terminal VBG1. When the transistor Tr is brought into conduction, the potential of the terminal PRE is supplied to the wiring SL.

Here, the transistor Tr2 and the transistor Tr3 are electrically connected to each other between the top gate of the transistor Tr and the terminal Sig. The transistor Tr2 and the transistor Tr3 function as a protection circuit. Each of the transistor Tr2 and the transistor Tr3 is a diode-connected transistor. In addition, a terminal VDD is electrically connected to the transistor Tr2, and a terminal VSS is electrically connected to the transistor Tr3. Furthermore, a terminal VBG2 is electrically connected to a back gate of the transistor Tr2, and a terminal VBG3 is electrically connected to a back gate of the transistor Tr3.

A circuit PC2 illustrated in FIG. 19B is an example of the case where the number of terminals and the number of transistors are reduced compared with those in the circuit PC1.

The circuit PC2 includes the transistor Tr1. The top gate of the transistor Tr is electrically connected to the wiring SL, the back gate of the transistor Tr is electrically connected to the terminal Sig, one of the source and the drain of the transistor Tr is electrically connected to the terminal PRE, and the other of the source and the drain of the transistor Tr is electrically connected to the wiring SL.

When the terminal Sig supplied with a control signal is connected not to the top gate of the transistor Tr but to the back gate of the transistor Tr in this manner, the terminal Sig does not require any protection circuit and thus the circuit can be simplified. Note that the top gate and the back gate of the transistor Tr can be interchanged in some cases depending on the electrical characteristics of the transistor Tr1.

A circuit PC3 illustrated in FIG. 19C is an example of the case where two transistors, a transistor Tr1a and a transistor Tr1b, are used instead of the transistor Tr in the circuit PC2. Back gates of the transistor Tr1a and the transistor Tr1b are electrically connected to the terminal Sig.

In addition, a circuit PC4 illustrated in FIG. 19D is an example of the case where terminals (a terminal Sig1 and a terminal Sig2) are connected to the transistor Tr1a and the transistor Tr1b, respectively.

With the structures illustrated in FIG. 19B, FIG. 19C, and FIG. 19D, the number of terminals can be significantly reduced compared with that in the structure illustrated in FIG. 19A, for example; therefore, a small display apparatus can be achieved.

At least part of this embodiment can be implemented in combination with the other embodiments described in this specification as appropriate.

### Embodiment 2

Structure examples of a display apparatus applicable to the display apparatus of the electronic device described as an example in Embodiment 1 will be described below with reference to drawings.

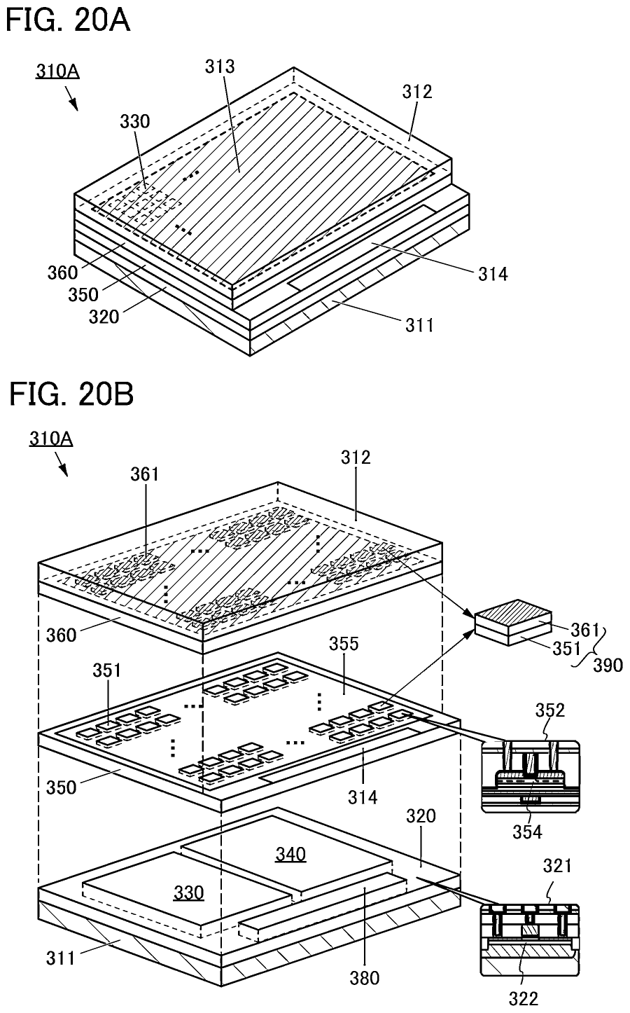

FIG. 20A is a perspective view of a display apparatus 310A applicable to the display apparatus of the electronic device described as an example in Embodiment 1.

The display apparatus 310A includes a substrate 311 and a substrate 312. The display apparatus 310A includes a display portion 313 composed of elements provided between the substrate 311 and the substrate 312. The display portion 313 is a region where an image is displayed in the display apparatus 310A. The display portion 313 includes a plurality of pixels 390. The pixels 390 each include a pixel circuit 351 and a light-emitting element 361.

In addition, by arranging the pixels 390 in a matrix of 1920×1080 pixels, the display portion 313 that can perform display with a resolution of what is called full high definition (also referred to as “2K resolution,” “2K1K,” “2K,” or the like) can be achieved. Alternatively, for example, by arranging the pixels 390 in a matrix of 3840×2160 pixels, the display portion 313 that can perform display with a resolution of what is called ultra-high definition (also referred to as “4K resolution,” “4K2K,” “4K,” or the like) can be achieved. Alternatively, for example, by arranging the pixels 390 in a matrix of 7680×4320 pixels, the display portion 313 that can perform display with a resolution of what is called super high definition (also referred to as “8K resolution,” “8K4K,” “8K,” or the like) can be achieved. By increasing the number of pixels 390, the display portion 313 that can perform display with 16K and 32K resolution can be also achieved.

In addition, the pixel density (definition) of the display portion 313 is preferably higher than or equal to 1000 ppi and lower than or equal to 10000 ppi. For example, the definition may be higher than or equal to 2000 ppi and lower than or equal to 6000 ppi, or higher than or equal to 3000 ppi and lower than or equal to 5000 ppi.

Note that there is no particular limitation on the screen ratio (aspect ratio) of the display portion 313. For example, the display portion 313 is compatible with a variety of screen ratios such as 1:1 (a square), 4:3, 16:9, and 16:10.

Note that in this specification and the like, the term “element” can be rephrased as the term “device” in some cases. For example, a display element, a light-emitting element, and a liquid crystal element can be rephrased as a display apparatus, a light-emitting device, and a liquid crystal device, respectively.

A variety of signals and power supply potentials are input to the display apparatus 310A from the outside via a terminal portion 314, so that an image can be displayed using a display element provided in the display portion 313. A variety of elements can be used as the display element. A light-emitting element having a function of emitting light, such as an organic EL element or an LED element, a liquid crystal element, a MEMS (Micro Electro Mechanical Systems) element, or the like can be typically employed.

A plurality of layers are provided between the substrate 311 and the substrate 312, and each of the layers is provided with a transistor for performing a circuit operation or a display element that emits light. A pixel circuit having a function of controlling the operation of the display element, a driver circuit having a function of controlling the pixel circuit, a functional circuit having a function of controlling the driver circuit, and the like are provided in the plurality of layers.

FIG. 20B illustrates a perspective view schematically illustrating structures of the layers provided between the substrate 311 and the substrate 312.

A layer 320 is provided over the substrate 311. The layer 320 includes a driver circuit 330, a functional circuit 340, and an input/output circuit 380. The layer 320 includes a transistor 321 containing silicon (also referred to as a Si transistor) in a channel formation region 322. The substrate 311 is a silicon substrate, for example. A silicon substrate is preferable because of having higher thermal conductivity than a glass substrate. When the driver circuit 330, the functional circuit 340, and the input/output circuit 380 are provided in the same layer, wirings electrically connecting the driver circuit 330, the functional circuit 340, and the input/output circuit 380 can be made short. Therefore, charge/discharge time of a control signal for controlling the driver circuit 330 by the functional circuit 340 becomes short, which leads to a reduction in power consumption. In addition, charge/discharge time for supplying a signal to the functional circuit 340 and the driver circuit 330 from the input/output circuit 380 becomes short, which leads to a reduction in power consumption.

The transistor 321 can be, for example, a transistor containing single crystal silicon in its channel formation region (such a transistor is also referred to as a “c-Si transistor”). In particular, the use of a transistor containing single crystal silicon in a channel formation region as the transistor provided in the layer 320 can increase the on-state current of the transistor. This is preferable because circuits included in the layer 320 can be driven at high speed. In addition, the Si transistor can be formed by microfabrication to have a channel length of greater than or equal to 3 nm and less than or equal to 10 nm, for example; thus, a CPU, an accelerator such as a GPU, an application processor, or the like can be integral with the display portion in the display apparatus 310A.

Alternatively, a transistor containing polycrystalline silicon in its channel formation region (such a transistor is also referred to as a “Poly-Si transistor”) may be provided in the layer 320. As polycrystalline silicon, low-temperature polysilicon (LTPS) may be used. Note that a transistor containing LTPS in its channel formation region is also referred to as an “LTPS transistor.” Alternatively, an OS transistor may be provided in the layer 320.

A variety of circuits such as a shift register, a level shifter, an inverter, a latch, an analog switch, and a logic circuit can be used as the driver circuit 330. The driver circuit 330 includes a gate driver circuit, a source driver circuit, or the like, for example. In addition, an arithmetic circuit, a memory circuit, a power supply circuit, and the like may be included. Since the gate driver circuit, the source driver circuit, and other circuits can be placed to overlap with the display portion 313, the width of a non-display region (also referred to as a bezel) that exists along the outer periphery of the display portion 313 of the display apparatus 310A can be made extremely narrow compared with the case where these circuits and the display portion 313 are placed side by side, so that miniaturization of the display apparatus 310A can be achieved.

The functional circuit 340 has a function of an application processor for controlling the circuits in the display apparatus 310A and generating signals for controlling the circuits, for example. In addition, the functional circuit 340 may include a CPU and a circuit for correcting image data, such as an accelerator (e.g., a GPU). Furthermore, the functional circuit 340 may include an LVDS (Low Voltage Differential Signaling) circuit, an MIPI (Mobile Industry Processor Interface) circuit, and/or a D/A (Digital to Analog) converter circuit, or the like having a function of an interface for receiving image data or the like from the outside of the display apparatus 310A. Moreover, the functional circuit 340 may include a circuit for compressing and decompressing image data and/or a power supply circuit, for example.

A layer 350 is provided over the layer 320. The layer 350 includes a pixel circuit group 355 including a plurality of pixel circuits 351. An OS transistor may be provided in the layer 350. Each of the pixel circuits 351 may include an OS transistor. Note that the layer 350 can be stacked and provided over the layer 320.

A Si transistor may be provided in the layer 350. For example, the pixel circuits 351 may each include a transistor containing single crystal silicon or polycrystalline silicon in its channel formation region. LTPS may be used as polycrystalline silicon. The layer 350 can be formed over another substrate and bonded to the layer 320, for example.

Alternatively, for example, the pixel circuits 351 may each include a plurality of kinds of transistors using different semiconductor materials. In the case where the pixel circuits 351 each include a plurality of kinds of transistors using different semiconductor materials, for example, the transistors may be provided in different layers for each kind of transistor. For example, in the case where the pixel circuits 351 each include a Si transistor and an OS transistor, the Si transistor and the OS transistor may be provided to overlap with each other. Providing the transistors to overlap with each other reduces the area occupied by the pixel circuits 351. Thus, the definition of the display apparatus 310A can be increased. Note that a structure where the LTPS transistor and the OS transistor are combined is referred to as LTPO in some cases.

A transistor that contains an oxide containing at least one of indium, an element M (the element M is aluminum, gallium, yttrium, or tin), and zinc in a channel formation region is preferably used as a transistor 352 that is an OS transistor. Such an OS transistor has a characteristic of extremely low off-state current. Thus, it is particularly preferable to use the OS transistor as a transistor provided in a pixel circuit because analog data written to the pixel circuit can be retained for a long period.

A layer 360 is provided over the layer 350. The substrate 312 is provided over the layer 360. The substrate 312 is preferably a substrate having a light-transmitting property or a layer formed using a material having a light-transmitting property. The layer 360 includes a plurality of light-emitting elements 361. Note that a structure where the layer 360 is stacked and provided over the layer 350 can be employed. As the light-emitting element 361, an organic electroluminescent element (also referred to as an organic EL element) or the like can be used, for example. Note that the light-emitting element 361 is not limited thereto, and an inorganic EL element formed using an inorganic material may be used, for example. Note that an “organic EL element” and an “inorganic EL element” are collectively referred to as an “EL element” in some cases. The light-emitting element 361 may contain an inorganic compound such as a quantum dot. For example, when a quantum dot is used for a light-emitting layer, the quantum dot can also function as a light-emitting material.

As illustrated in FIG. 20B, the display apparatus 310A according to one embodiment of the present invention can have a structure where the light-emitting elements 361, the pixel circuits 351, the driver circuit 330, and the functional circuit 340 are stacked; thus, the aperture ratio (effective display area ratio) of the pixels can be made extremely high. For example, the aperture ratio of the pixels can be greater than or equal to 40% and less than 100%, preferably greater than or equal to 50% and less than or equal to 95%, further preferably greater than or equal to 60% and less than or equal to 95%. Furthermore, the pixel circuits 351 can be placed extremely densely, and thus the definition of the pixels can be made extremely high. For example, the pixels can be placed in the display portion 313 of the display apparatus 310A (a region where the pixel circuits 351 and the light-emitting elements 361 are stacked) with a definition higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display apparatus 310A has extremely high definition, and thus can be suitably used for a device for VR such as a head-mounted display or a glasses-type device for AR. For example, even in the case of a structure where the display portion of the display apparatus 310A is seen through an optical member such as a lens, pixels of the extremely-high-definition display portion included in the display apparatus 310A are not seen when the display portion is enlarged by the lens, so that display providing a high sense of immersion can be performed.

Note that in the case where the display apparatus 310A is used as a display apparatus for VR or AR that is wearable, the display portion 313 can have a diagonal size greater than or equal to 0.1 inches and less than or equal to 5.0 inches, preferably greater than or equal to 0.5 inches and less than or equal to 2.0 inches, further preferably greater than or equal to 1 inch and less than or equal to 1.7 inches. For example, the display portion 313 may have a diagonal size of 1.5 inches or around 1.5 inches. When the display portion 313 has a diagonal size less than or equal to 2.0 inches, the number of times of light exposure treatment using a light exposure apparatus (typified by a scanner apparatus) can be one; thus, the productivity of a manufacturing process can be improved.

In addition, the display apparatus 310A according to one embodiment of the present invention can be employed for an electronic device other than a wearable electronic device. In that case, the display portion 313 may have a diagonal size greater than 2.0 inches. The structures of transistors used in the pixel circuit 351 may be selected as appropriate depending on the diagonal size of the display portion 313. In the case where single crystal Si transistors are used in the pixel circuit 351, for example, the diagonal size of the display portion 313 is preferably greater than or equal to 0.1 inches and less than or equal to 3 inches. In the case where LTPS transistors are used in the pixel circuit 351, the diagonal size of the display portion 313 is preferably greater than or equal to 0.1 inches and less than or equal to 30 inches, further preferably greater than or equal to 1 inch and less than or equal to 30 inches. Alternatively, in the case where LTPO (a structure where an LTPS transistor and an OS transistor are combined) is used in the pixel circuit 351, the diagonal size of the display portion 313 is preferably greater than or equal to 0.1 inches and less than or equal to 50 inches, further preferably greater than or equal to 1 inch and less than or equal to 50 inches. Alternatively, in the case where OS transistors are used in the pixel circuit 351, the diagonal size of the display portion 313 is preferably greater than or equal to 0.1 inches and less than or equal to 200 inches, further preferably greater than or equal to 50 inches and less than or equal to 100 inches.

An increase in the size of single crystal Si transistors is extremely difficult because an increase in the size of a single crystal Si substrate is difficult. In addition, since a laser crystallization apparatus is used in the manufacturing process when LTPS transistors are used in the display apparatus, it is difficult to support an increase in the size of the display apparatus using the LTPS transistors (typically a screen diagonal size greater than 30 inches). In contrast, since the manufacturing process of OS transistors does not necessarily require a laser crystallization apparatus or the like or the OS transistors can be manufactured at a comparatively low process temperature (typically, lower than or equal to 450° C.), the OS transistors are compatible with a display apparatus with a comparatively large area (typically, a diagonal size greater than or equal to 50 inches and less than or equal to 100 inches). Furthermore, LTPO is compatible with a diagonal size between sizes when using LTPS transistors and when using OS transistors (typically, greater than or equal to 1 inch and less than or equal to 50 inches).

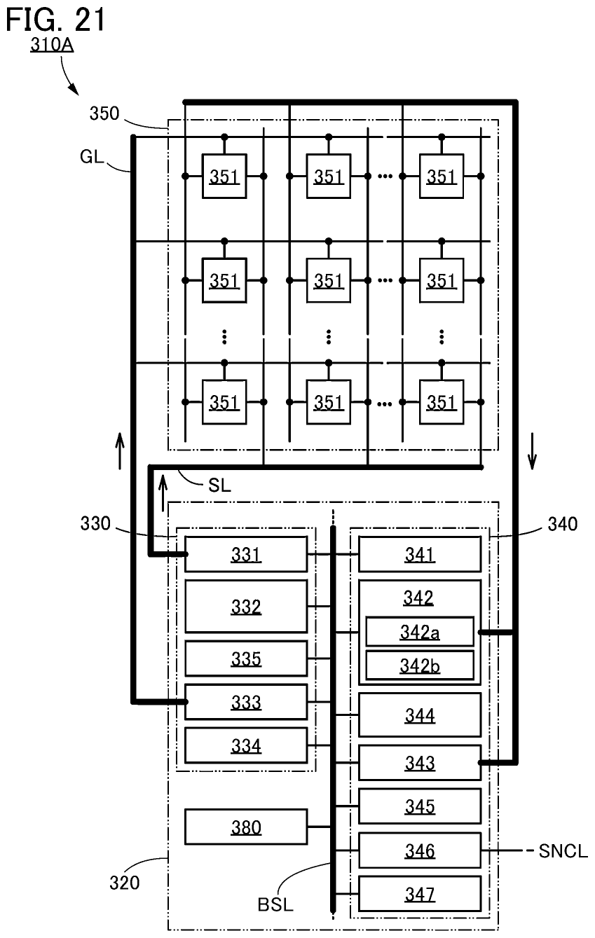

A specific structure example of the driver circuit 330 and the functional circuit 340 is described with reference to FIG. 21. FIG. 21 is a block diagram illustrating a plurality of wirings that connect the pixel circuits 351, the driver circuit 330, and the functional circuit 340 in the display apparatus 310A, a bus wiring in the display apparatus 310A, and the like.

In the display apparatus 310A illustrated in FIG. 21, the plurality of pixel circuits 351 are arranged in a matrix in the layer 350.

Furthermore, the driver circuit 330, the functional circuit 340, and the input/output circuit 380 are placed in the layer 320 in the display apparatus 310A illustrated in FIG. 21. The driver circuit 330 includes, for example, a source driver circuit 331, a digital-to-analog converter (DAC) circuit 332, an amplifier circuit 335, a gate driver circuit 333, and a level shifter 334. The functional circuit 340 includes, for example, a memory device 341, a GPU (AI accelerator) 342, an EL correction circuit 343, a timing controller 344, a CPU 345, a sensor controller 346, and a power supply circuit 347. The functional circuit 340 has a function of an application processor.

The input/output circuit 380 is compatible with a transmission method such as LVDS (Low Voltage Differential Signaling), and has a function of dividing control signals, image data, and the like input via the terminal portion 314 between the driver circuit 330 and the functional circuit 340. Furthermore, the input/output circuit 380 has a function of outputting data of the display apparatus 310A to the outside via the terminal portion 314.

In addition, the display apparatus 310A in FIG. 21 illustrates a structure example where the circuits included in the driver circuit 330 and the circuits included in the functional circuit 340 are each electrically connected to a bus wiring BSL.

The source driver circuit 331 has a function of transmitting image data to the pixel circuit 351 included in the pixel 390, for example. Thus, the source driver circuit 331 is electrically connected to the pixel circuit 351 through a wiring SL. Note that a plurality of source driver circuits 331 may be provided.

The digital-to-analog converter circuit 332 has a function of, for example, converting image data that has been digitally processed by a GPU described later, a correction circuit, or the like into analog data. Image data that has been converted into analog data is amplified by the amplifier circuit 335 such as an operational amplifier and is transmitted to the pixel circuit 351 via the source driver circuit 331. Note that a structure may be employed in which the image data is transmitted to the source driver circuit 331, the digital-to-analog converter circuit 332, and the pixel circuits 351 in this order. In addition, the digital-to-analog converter circuit 332 and the amplifier circuit 335 may be included in the source driver circuit 331.

The gate driver circuit 333 has a function of selecting a pixel circuit to which image data is to be transmitted in the pixel circuit 351, for example. Thus, the gate driver circuit 333 is electrically connected to the pixel circuit 351 through the wiring GL. Note that a plurality of gate driver circuits 333 may be provided so that the number of gate driver circuits 333 corresponds to the number of source driver circuits 331.

The level shifter 334 has a function of converting signals to be input to the source driver circuit 331, the digital-to-analog converter circuit 332, the gate driver circuit 333, and the like into signals having appropriate levels, for example.

The memory device 341 has a function of storing image data to be displayed by the pixel circuit 351, for example. Note that the memory device 341 can be configured to store the image data as digital data or analog data.

In addition, in the case where the memory device 341 stores image data, the memory device 341 is preferably a nonvolatile memory. In that case, a NAND type memory or the like can be employed as the memory device 341, for example.

Furthermore, in the case where the memory device 341 stores temporary data generated in the GPU 342, the EL correction circuit 343, the CPU 345, or the like, the memory device 341 is preferably a volatile memory. In that case, an SRAM (Static Random Access Memory), a DRAM (Dynamic Random Access Memory), or the like can be employed as the memory device 341, for example.

The GPU 342 has a function of performing processing for outputting image data read from the memory device 341 to the pixel circuit 351, for example. In particular, the GPU 342 is configured to perform pipeline processing in parallel and thus can perform high-speed processing of image data to be output to the pixel circuit 351. The GPU 342 can also have a function of a decoder for restoring an encoded image.

In addition, the functional circuit 340 may include a plurality of circuits that can improve the display quality of the display apparatus 310A. As such circuits, for example, correction circuits (dimming and toning) that detect color irregularity of a displayed image and correct the color irregularity to obtain an optimal image may be provided. In the case where a light-emitting device using organic EL is employed for the display element, for example, an EL correction circuit that corrects image data in accordance with the properties of the light-emitting device may be provided in the functional circuit 340. The functional circuit 340 includes, for example, the EL correction circuit 343.

In addition, artificial intelligence may be used for the above image correction. For example, current flowing through a pixel circuit (or voltage applied to the pixel circuit) may be monitored and acquired, a displayed image may be acquired with an image sensor or the like, the current (or voltage) and the image may be treated as input data in an arithmetic operation of artificial intelligence (e.g., an artificial neural network or the like), and whether to correct the image or not may be determined based on the output result.

Furthermore, such an arithmetic operation of artificial intelligence can be applied not only to image correction but also to upconversion processing for increasing the resolution of image data. As an example, the GPU 342 in FIG. 21 illustrates blocks for performing arithmetic operations for a variety of corrections (color irregularity correction 342a, upconversion 342b, and the like).

The upconversion processing of image data can be performed with an algorithm selected from a Nearest neighbor method, a Bilinear method, a Bicubic method, a RAISR (Rapid and Accurate Image Super-Resolution) method, an ANR (Anchored Neighborhood Regression) method, an A+ method, a SRCNN (Super-Resolution Convolutional Neural Network) method, and the like.

A structure may be employed in which the algorithm used for the upconversion processing is different in each region that is determined in accordance with a gaze point. For example, upconversion processing for a region including the gaze point and the vicinity of the gaze point is performed using an algorithm with low processing speed but high accuracy, and upconversion processing for a region other than the above region is performed using an algorithm with high processing speed but low accuracy. With this structure, the time required for the upconversion processing can be shortened. In addition, power consumption required for the upconversion processing can be reduced.

In addition, without limitation to upconversion processing, downconversion processing for decreasing the resolution of image data may be performed. In the case where the resolution of image data is higher than the resolution of the display portion 313, part of the image data is not displayed on the display portion 313 in some cases. In that case, downconversion processing enables the entire image data to be displayed on the display portion 313.

The timing controller 344 has a function of controlling drive frequency (frame frequency, frame rate, refresh rate, or the like) for displaying an image, for example. In the case where a still image is displayed on the display apparatus 310A, for example, the drive frequency is lowered by the timing controller 344, so that the power consumption of the display apparatus 310A can be reduced.

The CPU 345 has a function of performing general-purpose processing such as execution of an operating system, data control, and execution of a variety of arithmetic operations or programs, for example. The CPU 345 has a function of, for example, giving an instruction for a writing operation or a reading operation of image data in the memory device 341, an operation for correcting image data, an operation for a sensor described later, or the like. Furthermore, the CPU 345 may have a function of transmitting a control signal to at least one of the circuits included in the functional circuit 340, for example.

The sensor controller 346 has a function of controlling a sensor, for example. In addition, FIG. 21 illustrates a wiring SNCL as a wiring for electrical connection to the sensor.

The sensor can be, for example, a touch sensor that can be provided in the display portion 313. Alternatively, the sensor can be an illuminance sensor, for example.

The power supply circuit 347 has a function of generating voltage to be supplied to the pixel circuits 351, the driver circuit 330, the functional circuit 340, and the like. Note that the power supply circuit 347 may have a function of selecting a circuit to which voltage is to be supplied. The power supply circuit 347 stops supply of voltage to the CPU 345, the GPU 342, and the like during a period in which a still image is displayed, so that the power consumption of the whole display apparatus 310A can be reduced, for example.

As described above, the display apparatus according to one embodiment of the present invention can have a structure where the display element, the pixel circuits, the driver circuit, and the functional circuit 340 are stacked. The driver circuit and the functional circuit that are peripheral circuits can be placed to overlap with the pixel circuits and thus bezel width can be made extremely narrow, so that a display apparatus with reduced size can be achieved. Alternatively, when the display apparatus according to one embodiment of the present invention has a structure where circuits are stacked, wirings for connecting the circuits can be shortened, which results in a display apparatus with reduced weight. Alternatively, the display apparatus according to one embodiment of the present invention can be a display portion with high pixel definition; thus, the display apparatus according to one embodiment of the present invention can be a display apparatus having high display quality.

### <Structure Example of Display Module>

Next, a structure example of a display module including the display apparatus 310A is described below.

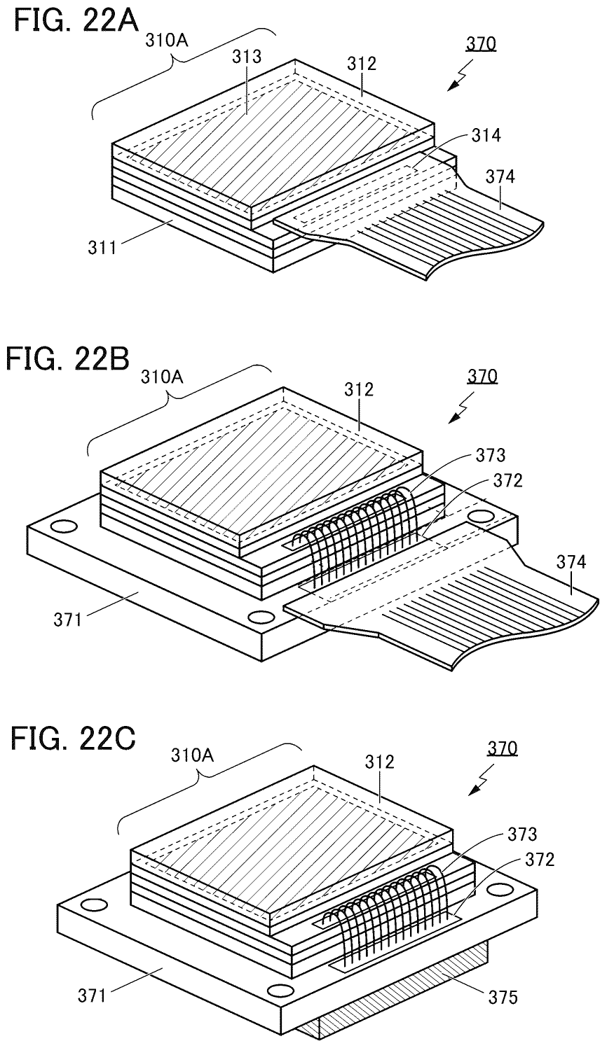

FIG. 22A to FIG. 22C are perspective views of a display module 370. The display module 370 has a structure where an FPC (Flexible printed circuits) 374 is provided on the terminal portion 314 of the display apparatus 310A. The FPC 374 has a structure where a film formed of an insulator is provided with a wiring. In addition, the FPC 374 is flexible. The FPC 374 functions as a wiring for supplying a video signal, a control signal, a power supply potential, and the like to the display apparatus 310A from the outside. Furthermore, an IC may be mounted on the FPC 374.

The display module 370 illustrated in FIG. 22B includes the display apparatus 310A over a printed wiring board 371. The printed wiring board 371 includes wirings inside a substrate formed of an insulator or on a surface of the substrate, or includes wirings inside the substrate and on the surface of the substrate.

In the display module 370 illustrated in FIG. 22B, the terminal portion 314 of the display apparatus 310A is electrically connected to a terminal portion 372 of the printed wiring board 371 through a wire 373. The wire 373 can be formed in wire bonding. In addition, ball bonding or wedge bonding can be used as the wire bonding.

After the wire 373 is formed, the wire 373 may be covered with a resin material or the like. Note that the display apparatus 310A and the printed wiring board 371 may be electrically connected to each other by a method other than the wire bonding. For example, the display apparatus 310A and the printed wiring board 371 may be electrically connected to each other using an anisotropic conductive adhesive, a bump, or the like.

In addition, in the display module 370 illustrated in FIG. 22B, the terminal portion 372 of the printed wiring board 371 is electrically connected to the FPC 374. In the case where the pitch between electrodes included in the terminal portion 314 of the display apparatus 310A is different from the pitch between electrodes included in the FPC 374, for example, the terminal portion 314 and the FPC 374 may be electrically connected to each other through the printed wiring board 371. Specifically, the distance (pitch) between a plurality of electrodes included in the terminal portion 314 can be converted into the distance between a plurality of electrodes included in the terminal portion 372 with the use of wirings formed on the printed wiring board 371. Accordingly, even in the case where the pitch between the electrodes included in the terminal portion 314 is different from the pitch between electrodes included in the FPC 374, electrical connection between the electrodes in the both can be obtained.

In addition, the printed wiring board 371 can be provided with a variety of elements such as a resistor, a capacitor, and a semiconductor element.

Furthermore, as in the display module 370 illustrated in FIG. 22C, the terminal portion 372 may be electrically connected to a connection portion 375 provided for a bottom surface (a surface where the display apparatus 310A is not provided) of the printed wiring board 371. With the use of a socket-type connection portion as the connection portion 375, for example, the display module 370 can be easily detached from and attached to another device.

### Embodiment 3

In this embodiment, a light-emitting device (light-emitting element) that can be used in the display apparatus according to one embodiment of the present invention will be described.

In this specification and the like, a device manufactured using a metal mask or an FMM (a fine metal mask or a high-definition metal mask) is sometimes referred to as a device having an MM (metal mask) structure. In addition, in this specification and the like, a device manufactured without using a metal mask or an FMM is sometimes referred to as a device having an MML (metal maskless) structure.

In this specification and the like, a structure where at least light-emitting layers of light-emitting devices having different emission wavelengths are separately formed is sometimes referred to as an SBS (Side By Side) structure. The SBS structure allows optimization of materials and structures of the light-emitting devices and thus can increase the degree of freedom in selecting the materials and the structures, which facilitates improvement in luminance and improvement in reliability.

In this specification and the like, a hole or an electron is sometimes referred to as a “carrier.” Specifically, a hole-injection layer or an electron-injection layer is sometimes referred to as a “carrier-injection layer,” a hole-transport layer or an electron-transport layer is sometimes referred to as a “carrier-transport layer,” and a hole-blocking layer or an electron-blocking layer is sometimes referred to as a “carrier-blocking layer.” Note that the carrier-injection layer, carrier-transport layer, and carrier-blocking layer cannot be distinguished from each other by cross-sectional shapes, characteristics, or the like in some cases. Furthermore, one layer has two or three functions of the carrier-injection layer, the carrier-transport layer, and the carrier-blocking layer in some cases.

In this specification and the like, a light-emitting device (also referred to as a light-emitting element) includes an EL layer between a pair of electrodes. The EL layer includes at least a light-emitting layer. Here, examples of a layer included in the EL layer (also referred to as a functional layer) include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

As the light-emitting device, an OLED (Organic Light Emitting Diode) or a QLED (Quantum-dot Light Emitting Diode) is preferably used, for example. Examples of a light-emitting substance contained in the light-emitting device include a substance exhibiting fluorescence (a fluorescent material), a substance exhibiting phosphorescence (a phosphorescent material), a substance exhibiting thermally activated delayed fluorescence (a thermally activated delayed fluorescent (TADF) material), and an inorganic compound (a quantum-dot material or the like). In addition, an LED (Light Emitting Diode) such as a micro-LED can be also used as the light-emitting device.

The emission color of the light-emitting device can be infrared, red, green, blue, cyan, magenta, yellow, white, or the like. Furthermore, color purity can be increased when the light-emitting device has a microcavity structure.

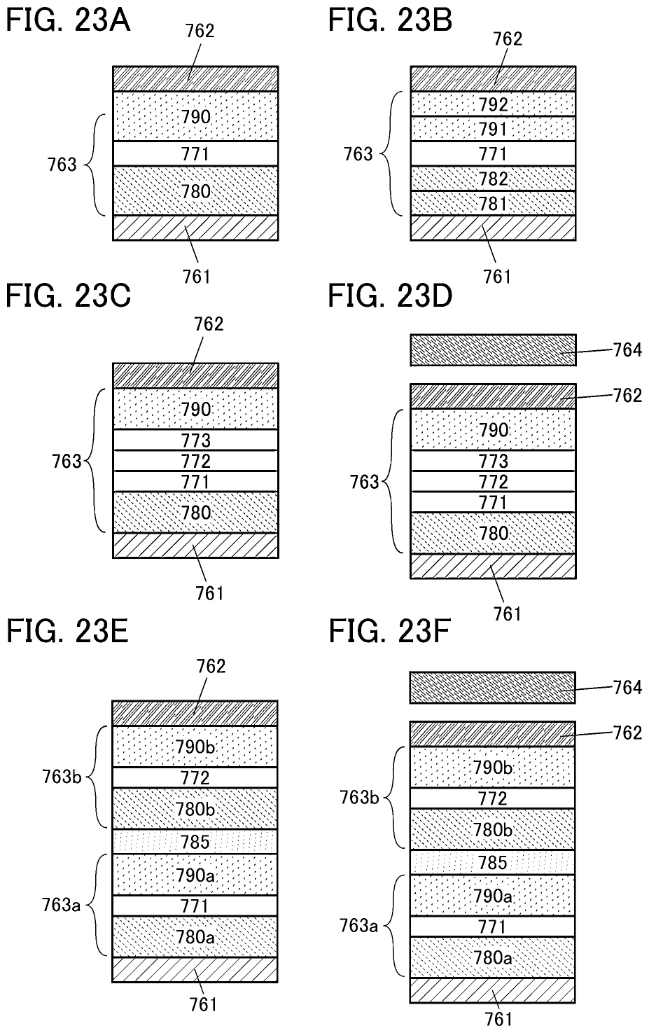

As illustrated in FIG. 23A, the light-emitting device includes an EL layer 763 between a pair of electrodes (a lower electrode 761 and an upper electrode 762). The EL layer 763 can be formed using a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (a hole-injection layer), a layer containing a substance having a high hole-transport property (a hole-transport layer), and a layer containing a substance having a high electron-blocking property (an electron-blocking layer). Furthermore, the layer 790 includes one or more of a layer containing a substance having a high electron-injection property (an electron-injection layer), a layer containing a substance having a high electron-transport property (an electron-transport layer), and a layer containing a substance having a high hole-blocking property (a hole-blocking layer). In the case where the lower electrode 761 is a cathode and the upper electrode 762 is an anode, the structures of the layers 780 and 790 are interchanged.

The structure including the layer 780, the light-emitting layer 771, and the layer 790 that is provided between the pair of electrodes can function as a single light-emitting unit, and the structure in FIG. 23A is referred to as a single structure in this specification.

In addition, FIG. 23B is a modification example of the EL layer 763 included in the light-emitting device illustrated in FIG. 23A. Specifically, the light-emitting device illustrated in FIG. 23B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. Alternatively, in the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layer structure, carriers can be efficiently injected to the light-emitting layer 771, and the efficiency of recombination of carriers in the light-emitting layer 771 can be increased.

Note that structures in which a plurality of light-emitting layers (light-emitting layers 771, 772, and 773) are provided between the layer 780 and the layer 790 as illustrated in FIG. 23C and FIG. 23D are other variations of the single structure. Note that although FIGS. 23C and 23D each illustrate the example where three light-emitting layers are included, the light-emitting device having the single structure may include two light-emitting layers or four or more light-emitting layers. In addition, the light-emitting device having the single structure may include a buffer layer between two light-emitting layers.

In addition, a structure where a plurality of light-emitting units (a light-emitting unit 763a and a light-emitting unit 763b) are connected in series with a charge-generation layer 785 (also referred to as an intermediate layer) therebetween as illustrated in FIG. 23E and FIG. 23F is referred to as a tandem structure in this specification. Note that the tandem structure may be referred to as a stack structure. The tandem structure enables a light-emitting device capable of light emission at high luminance. Furthermore, the tandem structure can reduce the amount of current needed for obtaining the same luminance as compared with the single structure, and thus can increase reliability.

Note that FIG. 23D and FIG. 23F each illustrate an example where the display apparatus includes a layer 764 overlapping with the light-emitting device. FIG. 23D illustrates an example where the layer 764 overlaps with the light-emitting device illustrated in FIG. 23C, and FIG. 23F illustrates an example where the layer 764 overlaps with the light-emitting device illustrated in FIG. 23E.

One or both of a color conversion layer and a color filter (a coloring layer) can be used for the layer 764.

In FIG. 23C and FIG. 23D, light-emitting substances that emit light of the same color or the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In addition, in each of a subpixel that emits red light and a subpixel that emits green light, a color conversion layer is provided as the layer 764 illustrated in FIG. 23D, so that blue light emitted from the light-emitting device can be converted into light with a longer wavelength and thus red light or green light can be extracted.

Alternatively, light-emitting substances that emit light of different colors may be used for the light-emitting layer 771, the light-emitting layer 772, and the light-emitting layer 773. White light emission can be obtained when the emission colors of the light-emitting layer 771, the light-emitting layer 772, and the light-emitting layer 773 are complementary colors. The light-emitting device having the single structure preferably includes a light-emitting layer containing a light-emitting substance that emits blue light and a light-emitting layer containing a light-emitting substance that emits visible light with a longer wavelength than blue light, for example.

In the case where the light-emitting device having the single structure includes three light-emitting layers, for example, a light-emitting layer containing a light-emitting substance that emits red (R) light, a light-emitting layer containing a light-emitting substance that emits green (G) light, and a light-emitting layer containing a light-emitting substance that emits blue (B) light are preferably included. The stacking order of the light-emitting layers can be R, G, and B from the anode side or R, B, and G from the anode side, for example. In that case, a buffer layer may be provided between R and G or between R and B.

In addition, in the case where the light-emitting device having the single structure includes two light-emitting layers, for example, a light-emitting layer containing a light-emitting substance that emits blue (B) light and a light-emitting layer containing a light-emitting substance that emits yellow (Y) light are preferably included. Such a structure is sometimes referred to as a BY single structure.

A color filter may be provided for the layer 764 illustrated in FIG. 23D. When white light passes through the color filter, light of a desired color can be obtained.

A light-emitting device that emits white light preferably contains two or more kinds of light-emitting substances. To obtain white light emission, two or more light-emitting substances are selected such that their emission colors are complementary colors. For example, when the emission color of a first light-emitting layer and the emission color of a second light-emitting layer are complementary colors, the light-emitting device can be configured to emit white light as a whole. The same applies to a light-emitting device including three or more light-emitting layers.

In addition, in FIG. 23E and FIG. 23F, light-emitting substances that emit light of the same color or the same light-emitting substance may be used for the light-emitting layer 771 and the light-emitting layer 772.

For example, in light-emitting devices included in subpixels that emit light of respective colors, a light-emitting substance that emits blue light may be used for each of the light-emitting layer 771 and the light-emitting layer 772. In a subpixel that emits blue light, blue light emitted from the light-emitting device can be extracted. In addition, in each of a subpixel that emits red light and a subpixel that emits green light, a color conversion layer is provided as the layer 764 illustrated in FIG. 23F, so that blue light emitted from the light-emitting device can be converted into light with a longer wavelength and thus red light or green light can be extracted.

Alternatively, in the case where the light-emitting device having the structure illustrated in FIG. 23E or FIG. 23F is used for the subpixels that emit light of respective colors, the subpixels may use different light-emitting substances. Specifically, in the light-emitting device included in the subpixel that emits red light, a light-emitting substance that emits red light may be used for each of the light-emitting layer 771 and the light-emitting layer 772. Similarly, in the light-emitting device included in the subpixel that emits green light, a light-emitting substance that emits green light may be used for each of the light-emitting layer 771 and the light-emitting layer 772. In the light-emitting device included in the subpixel that emits blue light, a light-emitting substance that emits blue light may be used for each of the light-emitting layer 771 and the light-emitting layer 772. A display apparatus having such a structure can be regarded as employing a light-emitting device with the tandem structure and the SBS structure. Thus, the display apparatus can have both the advantage of a tandem structure and the advantage of an SBS structure. Accordingly, a light-emitting device capable of light emission at high luminance and having high reliability can be achieved.

Alternatively, in FIG. 23E and FIG. 23F, light-emitting substances that emit light of different colors may be used for the light-emitting layer 771 and the light-emitting layer 772. White light emission can be obtained when light emitted from the light-emitting layer 771 and light emitted from the light-emitting layer 772 have complementary colors. A color filter may be provided as the layer 764 illustrated in FIG. 23F. When white light passes through the color filter, light of a desired color can be obtained.

Note that although FIG. 23E and FIG. 23F each illustrate an example where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

In addition, although FIG. 23E and FIG. 23F each illustrate the example of the light-emitting device including two light-emitting units, one embodiment of the present invention is not limited thereto. The light-emitting device may include three or more light-emitting units.

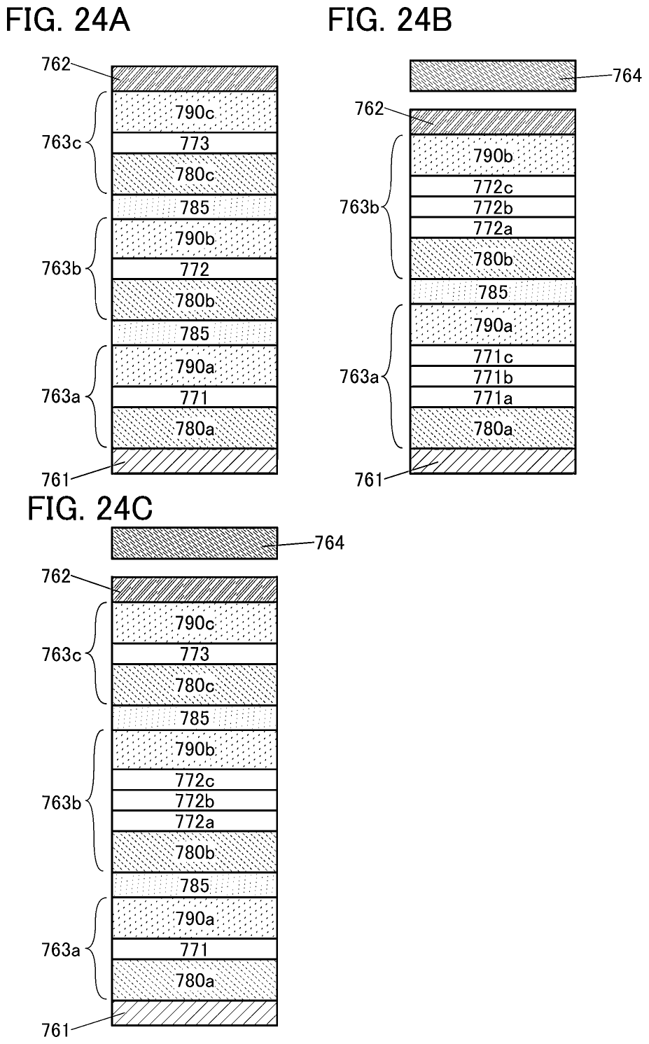

Specifically, structures of the light-emitting device illustrated in FIG. 24A to FIG. 24C can be given.

FIG. 24A illustrates a structure including three light-emitting units. Note that a structure including two light-emitting units and a structure including three light-emitting units may be referred to as a two-unit tandem structure and a three-unit tandem structure, respectively.

In addition, in the structure illustrated in FIG. 24A, a plurality of light-emitting units (the light-emitting unit 763a, the light-emitting unit 763b, and a light-emitting unit 763c) are connected in series with the charge-generation layers 785 therebetween. Furthermore, the light-emitting unit 763a includes a layer 780a, the light-emitting layer 771, and a layer 790a. The light-emitting unit 763b includes a layer 780b, the light-emitting layer 772, and a layer 790b. The light-emitting unit 763c includes a layer 780c, the light-emitting layer 773, and a layer 790c.

Note that in the structure illustrated in FIG. 24A, the light-emitting layer 771, the light-emitting layer 772, and the light-emitting layer 773 preferably contain light-emitting substances that emit light of the same color. Specifically, the light-emitting layer 771, the light-emitting layer 772, and the light-emitting layer 773 can each contain a light-emitting substance that emits red (R) light (what is called a three-unit R\R\R tandem structure), the light-emitting layer 771, the light-emitting layer 772, and the light-emitting layer 773 can each contain a light-emitting substance that emits green (G) light (what is called a three-unit G\G\G tandem structure), or the light-emitting layer 771, the light-emitting layer 772, and the light-emitting layer 773 can each contain a light-emitting substance that emits blue (B) light (what is called a three-unit B\B\B tandem structure).

Note that the structures of the light-emitting substances that emit light of the same color are not limited to the above structures. For example, a light-emitting device having a tandem structure may be employed in which light-emitting units each containing a plurality of light-emitting substances are stacked as illustrated in FIG. 24B. FIG. 24B illustrates a structure where a plurality of light-emitting units (the light-emitting unit 763a and the light-emitting unit 763b) are connected in series with the charge-generation layer 785 therebetween. In addition, the light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In the structure illustrated in FIG. 24B, the light-emitting unit 763a is configured to be able to emit white (W) light by selecting light-emitting substances for the light-emitting layer 771a, the light-emitting layer 771b, and the light-emitting layer 771c as appropriate. Furthermore, the light-emitting unit 763b is configured to be able to emit white (W) light by selecting light-emitting substances for the light-emitting layer 772a, the light-emitting layer 772b, and the light-emitting layer 772c as appropriate. That is, the structure illustrated in FIG. 24C is a two-unit W\W tandem structure. Note that there is no particular limitation on the stacking order of light-emitting substances that emit light of complementary colors in the light-emitting layer 771a, the light-emitting layer 771b, and the light-emitting layer 771c. A practitioner can select the optimal stacking order as appropriate. Moreover, although not illustrated, a three-unit W\W\W tandem structure or a tandem structure with four or more units may be employed.

In addition, in the case of using the light-emitting device having the tandem structure, the following structure can be given, for example: a two-unit B\Y tandem structure including a light-emitting unit that emits yellow (Y) light and a light-emitting unit that emits blue (B) light; a two-unit R·G\B tandem structure including a light-emitting unit that emits red (R) and green (G) light and a light-emitting unit that emits blue (B) light; a three-unit B\Y\B tandem structure including a light-emitting unit that emits blue (B) light, a light-emitting unit that emits yellow (Y) light, and a light-emitting unit that emits blue (B) light in this order; a three-unit B\Y·G\B tandem structure including a light-emitting unit that emits blue (B) light, a light-emitting unit that emits yellowish-green (YG) light, and a light-emitting unit that emits blue (B) light in this order; and a three-unit B\G\B tandem structure including a light-emitting unit that emits blue (B) light, a light-emitting unit that emits green (G) light, and a light-emitting unit that emits blue (B) light in this order.

Alternatively, a light-emitting unit containing one light-emitting substance and a light-emitting unit containing a plurality of light-emitting substances may be used in combination as illustrated in FIG. 24C.

Specifically, in the structure illustrated in FIG. 24C, a plurality of light-emitting units (the light-emitting unit 763a, the light-emitting unit 763b, and the light-emitting unit 763c) are connected in series with the charge-generation layers 785 therebetween. In addition, the light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

In the structure illustrated in FIG. 24C, for example, a three-unit B\R·G·YG\B tandem structure where the light-emitting unit 763a is a light-emitting unit that emits blue (B) light, the light-emitting unit 763b is a light-emitting unit that emits red (R), green (G), and yellowish-green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from the anode side include a two-layer structure of R and Y, a two-layer structure of R and G, a two-layer structure of G and R, a three-layer structure of G, R, and G, and a three-layer structure of R, G, and R. In addition, another layer may be provided between two light-emitting layers.

Note that also in FIG. 23C and FIG. 23D, the layer 780 and the layer 790 may each independently have a stacked-layer structure of two or more layers as illustrated in FIG. 23B.

In addition, in FIG. 23E and FIG. 23F, the light-emitting unit 763a includes the layer 780a, the light-emitting layer 771, and the layer 790a, and the light-emitting unit 763b includes the layer 780b, the light-emitting layer 772, and the layer 790b.

In the case where the lower electrode 761 is an anode and the upper electrode 762 is a cathode, the layer 780a and the layer 780b each include one or more of a hole-injection layer, a hole-transport layer, and an electron-blocking layer. Furthermore, the layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are interchanged, and the structures of the layer 780b and the layer 790b are also interchanged.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. In addition, the layer 790a includes an electron-transport layer, and may further include a hole-blocking layer between the light-emitting layer 771 and the electron-transport layer. Furthermore, the layer 780b includes a hole-transport layer, and may further include an electron-blocking layer over the hole-transport layer. Moreover, the layer 790b includes an electron-transport layer and an electron-injection layer over the electron-transport layer, and may further include a hole-blocking layer between the light-emitting layer 771 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. In addition, the layer 790a includes a hole-transport layer, and may further include an electron-blocking layer between the light-emitting layer 771 and the hole-transport layer. Furthermore, the layer 780b includes an electron-transport layer, and may further include a hole-blocking layer over the electron-transport layer. Moreover, the layer 790b includes a hole-transport layer and a hole-injection layer over the hole-transport layer, and may further include an electron-blocking layer between the light-emitting layer 771 and the hole-transport layer.

In addition, in the case of manufacturing the light-emitting device having the tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other of the two light-emitting units when voltage is applied between the pair of electrodes.

In particular, the display apparatus according to one embodiment of the present invention preferably has a structure where the light-emitting device that emits white light is combined with a color filter. In addition, the display apparatus according to one embodiment of the present invention further preferably has the light-emitting device having the tandem structure.

Next, materials that can be used for the light-emitting device are described.

A conductive film that transmits visible light is used for the electrode through which light is extracted, which is either the lower electrode 761 or the upper electrode 762. A conductive film that reflects visible light is preferably used for the electrode through which light is not extracted. Alternatively, in the case where the display apparatus includes a light-emitting device that emits infrared light, it is preferable that a conductive film that transmits visible light and infrared light be used as the electrode through which light is extracted and that a conductive film that reflects visible light and infrared light be used as the electrode through which light is not extracted.

A conductive film that transmits visible light may be used also for the electrode through which light is not extracted. In that case, the electrode is preferably placed between a reflective layer and the EL layer 763. In other words, light emitted from the EL layer 763 may be reflected by the reflective layer to be extracted from the display apparatus.

As a material that forms the pair of electrodes of the light-emitting device, a metal, an alloy, an electrically conductive compound, a mixture thereof, or the like can be used as appropriate. Specific examples of the material include metals such as aluminum, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing an appropriate combination of these metals. Other examples of the material include indium tin oxide (also referred to as In—Sn oxide or ITO), an In—Si—Sn oxide (also referred to as ITSO), indium zinc oxide (an In—Zn oxide), and an In—W—Zn oxide. Other examples of the material include an alloy containing aluminum (an aluminum alloy) such as an alloy of aluminum, nickel, and lanthanum (Al—Ni—La), and an alloy of silver, palladium, and copper (Ag—Pd—Cu, also referred to as APC). Other examples of the material include an element that belongs to Group 1 or Group 2 of the periodic table, which is not described above (e.g., lithium, cesium, calcium, or strontium), a rare earth metal such as europium or ytterbium, an alloy containing an appropriate combination of these elements, and graphene.

The light-emitting device preferably employs a microcavity structure. Therefore, one of the pair of electrodes of the light-emitting device preferably includes an electrode having properties of transmitting and reflecting visible light (a semi-transmissive and semi-reflective electrode), and the other of the pair of electrodes of the light-emitting device preferably includes an electrode having a property of reflecting visible light (a reflective electrode). When the light-emitting device has a microcavity structure, light obtained from the light-emitting layer can be resonated between the electrodes, so that light emitted from the light-emitting device can be intensified.

Note that the semi-transmissive and semi-reflective electrode can have a stacked-layer structure of a conductive layer that can be used for a reflective electrode and a conductive layer that can be used for a conductive layer having a property of transmitting visible light (also referred to as a transparent electrode).

The transparent electrode has a light transmittance higher than or equal to 40%. For example, an electrode having a visible light (light at a wavelength greater than or equal to 400 nm and less than 750 nm) transmittance higher than or equal to 40% is preferably used as the transparent electrode in the light-emitting device. The visible light reflectance of the semi-transmissive and semi-reflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. In addition, these electrodes preferably have a resistivity lower than or equal to 1×10⁻² Ωcm.

The light-emitting device includes at least a light-emitting layer. In addition, the light-emitting device may further include, as a layer other than the light-emitting layer, a layer containing a substance having a high hole-injection property, a substance having a high hole-transport property, a hole-blocking material, a substance having a high electron-transport property, a substance having a high electron-injection property, an electron-blocking material, a substance having a bipolar property (a substance having a high electron-transport property and a high hole-transport property), or the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may be contained. Each layer included in the light-emitting device can be formed by a method such as an evaporation method (including a vacuum evaporation method), a transfer method, a printing method, an inkjet method, or a coating method.

The light-emitting layer contains one or more kinds of light-emitting substances. As the light-emitting substance, a substance that exhibits an emission color of blue, violet, bluish violet, green, yellowish green, yellow, orange, red, or the like is used as appropriate. Alternatively, as the light-emitting substance, a substance that emits near-infrared light can be used.

Examples of the light-emitting substance include a fluorescent material, a phosphorescent material, a TADF material, and a quantum-dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (a host material, an assist material, and the like) in addition to the light-emitting substance (guest material). As one or more kinds of organic compounds, one or both of a substance having a high hole-transport property (a hole-transport material) and a substance having a high electron-transport property (an electron-transport material) can be used. As the hole-transport material, it is possible to use a material having a high hole-transport property that can be used for the hole-transport layer and will be described later. As the electron-transport material, it is possible to use a material having a high electron-transport property that can be used for the electron-transport layer and will be described later. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength is to overlap with the wavelength of the lowest-energy-side absorption band of the light-emitting substance, energy can be smoothly transferred and light emission can be efficiently obtained. With this structure, high efficiency, low-voltage driving, and a long lifetime of the light-emitting device can be achieved at the same time.

The hole-injection layer is a layer injecting holes from an anode to the hole-transport layer and a layer containing a material having a high hole-injection property. Examples of the material having a high hole-injection property include an aromatic amine compound and a composite material containing a hole-transport material and an acceptor material (an electron-accepting material).

As the hole-transport material, it is possible to use a material having a high hole-transport property that can be used for the hole-transport layer and will be described later.

As the acceptor material, an oxide of a metal that belongs to Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable because it is stable in the air, has a low hygroscopic property, and is easy to handle. Alternatively, an organic acceptor material containing fluorine can be used. Alternatively, an organic acceptor material such as a quinodimethane derivative, a chloranil derivative, and a hexaazatriphenylene derivative can be used.

For example, a hole-transport material and a material containing an oxide of a metal that belongs to Group 4 to Group 8 of the periodic table (typically, molybdenum oxide) may be used as the material having a high hole-injection property.

The hole-transport layer is a layer transporting holes, which are injected from the anode by the hole-injection layer, to the light-emitting layer. The hole-transport layer is a layer containing a hole-transport material. For the hole-transport material, a substance having a hole mobility higher than or equal to 1×10⁻⁶ cm²/Vs is preferable. Note that other substances can be also used as long as they have a property of transporting more holes than electrons. As the hole-transport material, a material having a high hole-transport property, such as a Tc-electron rich heteroaromatic compound (e.g., a carbazole derivative, a thiophene derivative, a furan derivative, or the like) or an aromatic amine (a compound having an aromatic amine skeleton), is preferable.

The electron-blocking layer is provided in contact with the light-emitting layer. The electron-blocking layer has a hole-transport property and contains a material capable of blocking electrons. The materials having an electron-blocking property among the above hole-transport materials can be used for the electron-blocking layer.

The electron-blocking layer has a hole-transport property, and thus can be also referred to as a hole-transport layer. In addition, a layer having an electron-blocking property among the hole-transport layers can be also referred to as an electron-blocking layer.

The electron-transport layer is a layer transporting electrons, which are injected from the cathode by the electron-injection layer, to the light-emitting layer. The electron-transport layer is a layer containing an electron-transport material. As the electron-transport material, a substance having an electron mobility higher than or equal to 1×10⁻⁶ cm²/Vs is preferable. Note that other substances can be also used as long as they have a property of transporting more electrons than holes. As the electron-transport material, it is possible to use a material having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a Tc-electron deficient heteroaromatic compound such as a nitrogen-containing heteroaromatic compound.

The hole-blocking layer is provided in contact with the light-emitting layer. The hole-blocking layer has an electron-transport property and contains a material capable of blocking holes. The materials having a hole-blocking property among the above electron-transport materials can be used for the hole-blocking layer.

The hole-blocking layer has an electron-transport property, and thus can be also referred to as an electron-transport layer. In addition, a layer having a hole-blocking property among the electron-transport layers can be also referred to as a hole-blocking layer.

The electron-injection layer is a layer injecting electrons from the cathode to the electron-transport layer and a layer containing a material having a high electron-injection property. As the material having a high electron-injection property, an alkali metal, an alkaline earth metal, or a compound thereof can be used. As the material having a high electron-injection property, a composite material containing an electron-transport material and a donor material (an electron-donating material) can be also used.

In addition, the difference between the LUMO level of the material having a high electron-injection property and the work function value of the material used for the cathode is preferably small (specifically, smaller than or equal to 0.5 eV).

For the electron-injection layer, an alkali metal, an alkaline earth metal, or a compound thereof, such as lithium, cesium, ytterbium, lithium fluoride (LiF), cesium fluoride (CsF), calcium fluoride (CaF_{X}, where X is a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOₓ), or cesium carbonate can be used, for example. In addition, the electron-injection layer may have a stacked-layer structure of two or more layers. As the stacked-layer structure, for example, a structure where lithium fluoride is used for a first layer and ytterbium is provided for a second layer can be given.

The electron-injection layer may include an electron-transport material. For example, a compound having an unshared electron pair and an electron deficient heteroaromatic ring can be used for the electron-transport material. Specifically, a compound having at least one of a pyridine ring, a diazine ring (a pyrimidine ring, a pyrazine ring, and a pyridazine ring), and a triazine ring can be used.

Note that the lowest unoccupied molecular orbital (LUMO) level of the organic compound having an unshared electron pair is preferably higher than or equal to −3.6 eV and lower than or equal to −2.3 eV. In addition, in general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used for the organic compound having an unshared electron pair. Note that NBPhen has a higher glass transition point (Tg) than BPhen and thus has high heat resistance.

As described above, the charge-generation layer includes at least a charge-generation region. The charge-generation region preferably contains an acceptor material, and for example, preferably contains a hole-transport material and an acceptor material that can be employed for the hole-injection layer.

In addition, the charge-generation layer preferably includes a layer containing a material having a high electron-injection property. The layer can be also referred to as an electron-injection buffer layer. The electron-injection buffer layer is preferably provided between the charge-generation region and the electron-transport layer. By providing the electron-injection buffer layer, an injection barrier between the charge-generation region and the electron-transport layer can be lowered; thus, electrons generated in the charge-generation region can be easily injected into the electron-transport layer.

The electron-injection buffer layer preferably contains an alkali metal or an alkaline earth metal, and for example, can contain an alkali metal compound or an alkaline earth metal compound. Specifically, the electron-injection buffer layer preferably contains an inorganic compound containing an alkali metal and oxygen or an inorganic compound containing an alkaline earth metal and oxygen, further preferably contains an inorganic compound containing lithium and oxygen (lithium oxide (Li₂O) or the like). Alternatively, a material that can be employed for the electron-injection layer can be suitably used for the electron-injection buffer layer.

The charge-generation layer preferably includes a layer containing a material having a high electron-transport property. The layer can be also referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper(II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from each other by cross-sectional shapes, characteristics, or the like in some cases.

Note that the charge-generation layer may contain a donor material instead of an acceptor material. For example, the charge-generation layer may include a layer containing an electron-transport material and a donor material that can be employed for the electron-injection layer.

When the light-emitting units are stacked, provision of a charge-generation layer between two light-emitting units can inhibit an increase in drive voltage.

At least part of the structure examples, the drawings corresponding thereto, and the like described in this embodiment can be combined with the other structure examples, the other drawings corresponding thereto, and the like as appropriate.

### Embodiment 4

In this embodiment, structure examples of an electronic device to which the display apparatus according to one embodiment of the present invention is applied will be described.

The display apparatus and the display module according to one embodiment of the present invention can be applied to a display portion of an electronic device or the like having a display function. Examples of such an electronic device include a digital camera, a digital video camera, a digital photo frame, a cellular phone, a portable game machine, a portable information terminal, and an audio reproducing device, in addition to an electronic device with a comparatively large screen, such as a television device, a laptop personal computer, a monitor device, digital signage, a pachinko machine, or a game machine.

In particular, the display apparatus and the display module according to one embodiment of the present invention can have high definition, and thus can be suitably used for an electronic device with a comparatively small display portion. Examples of such an electronic device include a watch-type or bracelet-type information terminal device (wearable device) and a wearable device worn on a head, such as a device for VR such as a head mounted display and a glasses-type device for AR.

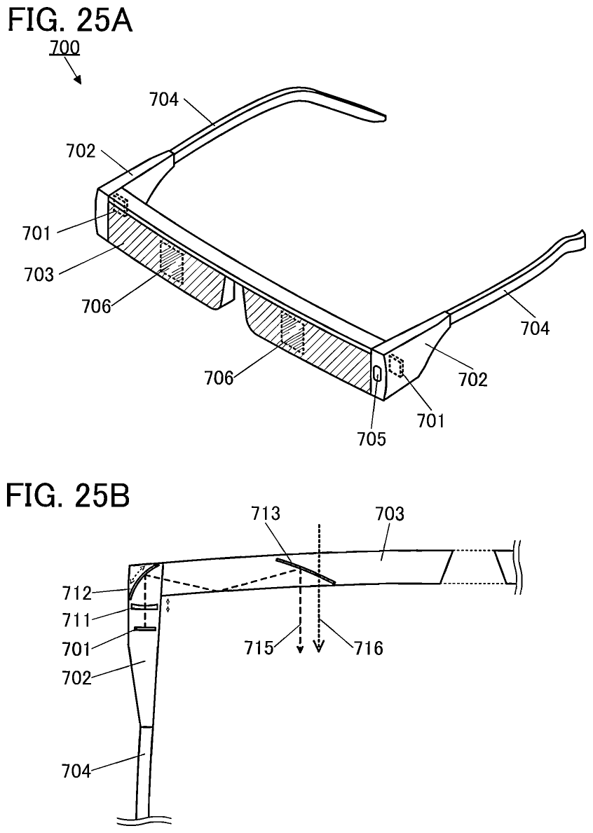

FIG. 25A is a perspective view of a glasses-type electronic device 700. The electronic device 700 includes a pair of display panels 701, a pair of housings 702, a pair of optical members 703, a pair of wearing portions 704, and the like.

The electronic device 700 can project an image displayed on the display panel 701 onto a display region 706 of the optical member 703. In addition, since the optical members 703 have a light-transmitting property, a user can see images that are displayed on the display regions 706 and are superimposed on transmission images seen through the optical members 703. Thus, the electronic device 700 is an electronic device capable of AR display.

One housing 702 is provided with a camera 705 capable of taking an image of what lies in front thereof. Although not illustrated, one of the housings 702 is provided with a wireless receiver or a connector to which a cable can be connected, so that a video signal or the like can be supplied to the housing 702. Furthermore, when the housing 702 is provided with an acceleration sensor such as a gyroscope sensor, the orientation of the user's head can be detected and an image corresponding to the orientation can be displayed on the display region 706. Moreover, the housing 702 is preferably provided with a battery because charging can be performed with or without a wire.

Next, a method for projecting an image on the display region 706 of the electronic device 700 is described using FIG. 25B. The display panel 701, a lens 711, and a reflective plate 712 are provided in the housing 702. In addition, a reflective surface 713 functioning as a half mirror is provided in a portion corresponding to the display region 706 of the optical member 703.

Light 715 emitted from the display panel 701 passes through the lens 711 and is reflected by the reflective plate 712 to the optical member 703 side. In the optical member 703, the light 715 is fully reflected repeatedly by end surfaces of the optical member 703 and reaches the reflective surface 713, so that an image is projected on the reflective surface 713. Accordingly, the user can see both the light 715 reflected by the reflective surface 713 and transmitted light 716 transmitted through the optical member 703 (including the reflective surface 713).

FIG. 25 illustrates an example where the reflective plate 712 and the reflective surface 713 each have a curved surface. This structure can increase optical design flexibility and reduce the thickness of the optical member 703, compared to the case where the reflective plate 712 and the reflective surface 713 are flat. Note that the reflective plate 712 and the reflective surface 713 may be flat.

A component having a mirror surface can be used for the reflective plate 712, and the reflective plate 712 preferably has high reflectance. In addition, as the reflective surface 713, a half mirror utilizing reflection of a metal film may be used, but the use of a prism utilizing total reflection or the like can increase the transmittance of the transmitted light 716.

Here, the housing 702 preferably includes a mechanism for adjusting the distance or angle between the lens 711 and the display panel 701. This enables focus adjustment, zooming in/out of an image, or the like. One or both of the lens 711 and the display panel 701 are preferably configured to be movable in an optical-axis direction, for example.

In addition, the housing 702 preferably includes a mechanism capable of adjusting the angle of the reflective plate 712. The position of the display region 706 where images are displayed can be changed by changing the angle of the reflective plate 712. Thus, the display region 706 can be placed at the most appropriate position in accordance with the position of the user's eye.

The display apparatus or the display module according to one embodiment of the present invention can be applied to the display panel 701. Thus, the electronic device 700 can perform display with extremely high definition.

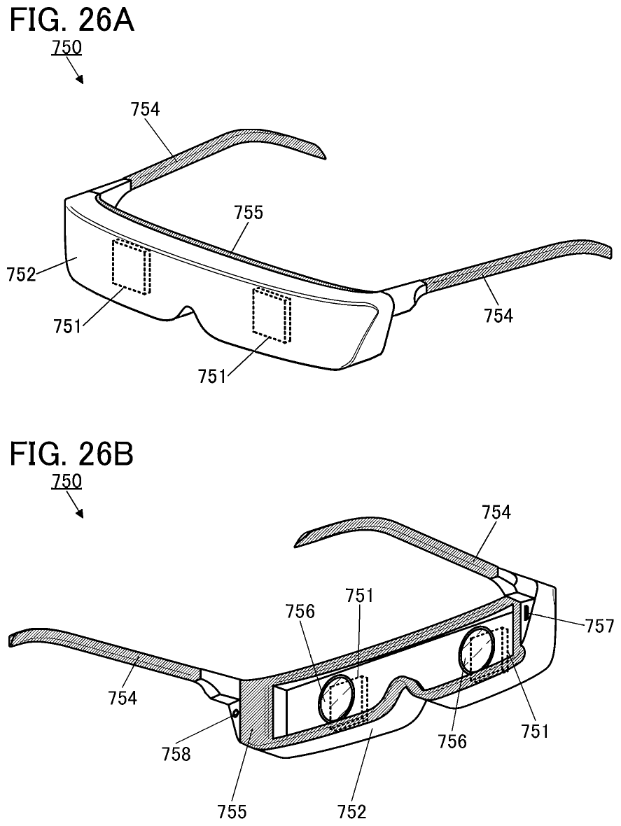

FIG. 26A and FIG. 26B are perspective views of a goggle-type electronic device 750. FIG. 26A is a perspective view illustrating the front surface, top surface, and left side surface of the electronic device 750, and FIG. 26B is a perspective view illustrating the back surface, bottom surface, and right side surface of the electronic device 750.

The electronic device 750 includes a pair of display panels 751, a housing 752, a pair of wearing portions 754, a shock-absorbing material 755, a pair of lenses 756, and the like. The pair of display panels 751 is positioned to be seen through the lenses 756 inside the housing 752.

The electronic device 750 is an electronic device for VR. A user wearing the electronic device 750 can see an image displayed on the display panel 751 through the lens 756. Furthermore, when the pair of display panels 751 displays different images, three-dimensional display using parallax can be performed.

In addition, an input terminal 757 and an output terminal 758 are provided on the back side of the housing 752. To the input terminal 757, a cable for supplying a video signal from a video output device or the like, power for charging a battery provided in the housing 752, or the like can be connected. The output terminal 758 can function as, for example, an audio output terminal to which earphones, headphones, or the like can be connected. Note that in the case where audio data can be output by wireless communication or sound is output from an external video output device, the audio output terminal is not necessarily provided.

In addition, the housing 752 preferably includes a mechanism by which the right and left positions of the lens 756 and the display panel 751 can be adjusted to the most appropriate positions in accordance with the position of the user's eye. Furthermore, the housing 752 preferably includes a mechanism for adjusting focus by changing the distance between the lens 756 and the display panel 751.

The display apparatus or the display module according to one embodiment of the present invention can be applied to the display panel 751. Thus, the electronic device 750 can perform display with extremely high definition. This enables a user to feel a high sense of immersion.

The shock-absorbing material 755 is a portion in contact with the user's face (forehead, cheek, or the like). The shock-absorbing material 755 is in close contact with the user's face, so that light leakage can be prevented, which further increases the sense of immersion. A soft material is preferably used for the shock-absorbing material 755 so that the shock-absorbing material 755 is in close contact with the face of the user wearing the electronic device 750. For example, a material such as rubber, silicone rubber, urethane, or a sponge can be used. Furthermore, when a sponge or the like whose surface is covered with cloth, leather (natural leather or synthetic leather), or the like is used, a gap is less likely to be generated between the user's face and the shock-absorbing material 755, so that light leakage can be suitably prevented.

Furthermore, using such a material is preferable because it has a soft texture and the user does not feel cold when wearing the device in a cold season, for example. The member in contact with user's skin, such as the shock-absorbing material 755 or the wearing portion 754, is preferably detachable because cleaning or replacement can be easily performed.

At least part of this embodiment can be implemented in combination with the other embodiments described in this specification as appropriate.

### Example

In this example, a display panel according to one embodiment of the present invention was manufactured.

The display panel was manufactured using a single crystal silicon substrate as a substrate by sequentially stacking a single crystal silicon transistor, a wiring layer, an oxide semiconductor transistor (an OS transistor), and light-emitting elements. As each of the light-emitting elements, a white light-emitting element with a B\Y tandem structure where a light-emitting layer that emits blue (B) light and a light-emitting layer that emits yellow (Y) light are stacked was employed. In addition, a protective layer was formed over the light-emitting elements, and a color filter and a lens were formed over the protective layer.

The manufactured display panel has a display region diagonal size of 0.51 inches, a resolution of 1920×1920 pixels, a pixel size of 4.8 μm, and a pixel density of 5291 ppi. Each of the light-emitting elements is a top-emission type.

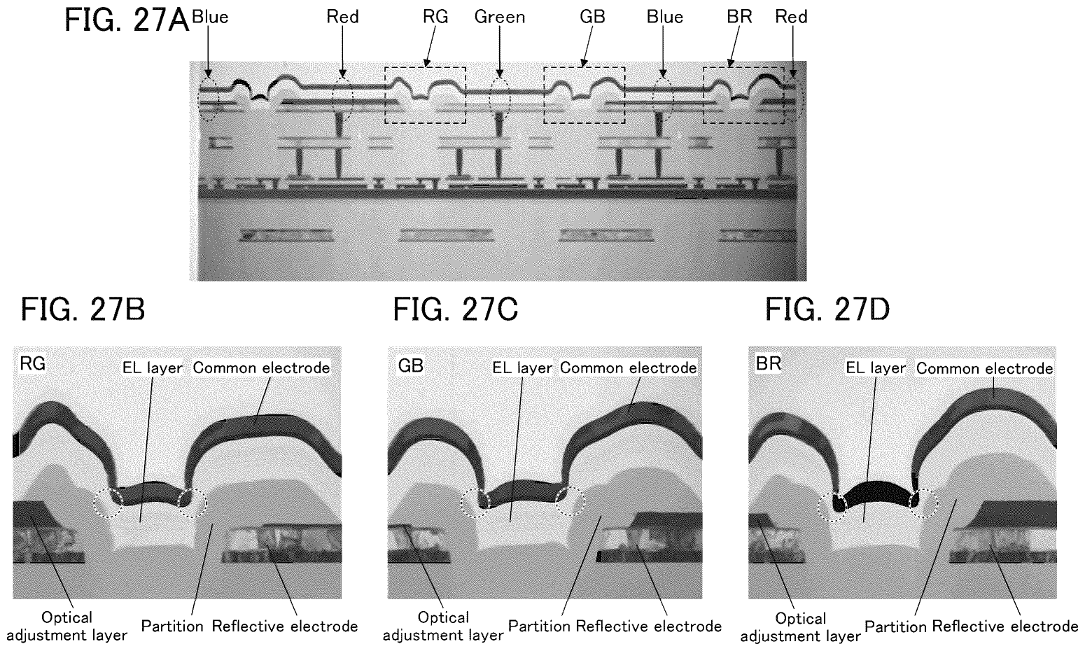

FIG. 27A shows a cross-sectional observation image of a manufactured display apparatus. FIG. 27A shows cross sections of light-emitting elements that correspond to Blue, Red, Green, Blue, and Red pixels from left to right. A region between Red and Green is referred to as a region RG, a region between Green and Blue is referred to as a region GB, a region between Blue and Red is referred to as a region BR.

FIG. 27B, FIG. 27C, and FIG. 27D show enlarged images of the region RG, the region GB, and the region BR, respectively. A reflective electrode (also referred to as a conductive layer), an optical adjustment layer (also referred to as a conductive layer) over the reflective electrode, a partition (also referred to as an insulating layer) that covers end portions of the reflective electrode and the optical adjustment layer, an EL layer, and a common electrode (also referred to as a conductive layer) are provided in each of these diagrams.

In each of these diagrams, as shown by dashed circles, it can be confirmed that the EL layer in regions overlapping with the partition has portions whose thicknesses are less than those of other portions. The minimum value and the maximum value of the measured thicknesses of six portions shown by the dashed circles in FIG. 27B, FIG. 27C, and FIG. 27D were 24.4 nm and 49.8 nm, respectively. In consideration of the fact that the thickness of the EL layer in a region where the EL layer overlaps with a pixel electrode and the partition is approximately 200 nm, it can be confirmed that the EL layer has a portion with a thickness of approximately 12.2% to 24.9% of the thickness of the EL layer overlapping with the pixel electrode and the partition.

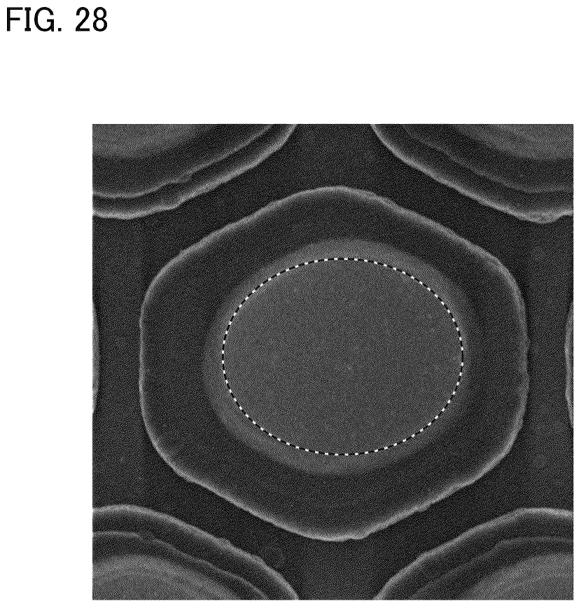

FIG. 28 shows a top-view observation image of one light-emitting element. A region shown by a dashed circle corresponds to a light-emitting region. The shape of the light-emitting region is an elliptical shape with a height of approximately 1.5 m and a width of approximately 1.8 m. The aperture ratio was approximately 25.9%.

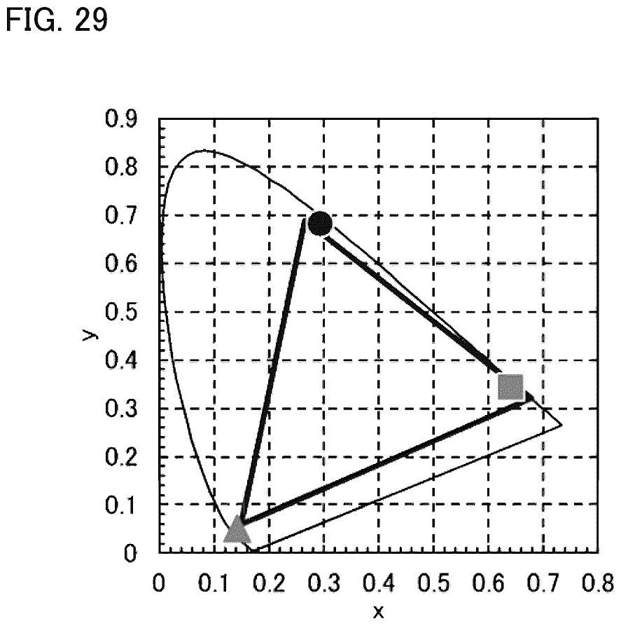

FIG. 29 shows a chromaticity diagram. In FIG. 29, a chromaticity coordinate when the manufactured display panel emits red light is shown by a rectangular marker, a chromaticity coordinate when the display panel emits green light is shown by a circular marker, and a chromaticity coordinate when the display panel emits blue light is shown by a triangular marker. The DCI-P3 coverage rate of the display panel was 87.4%.

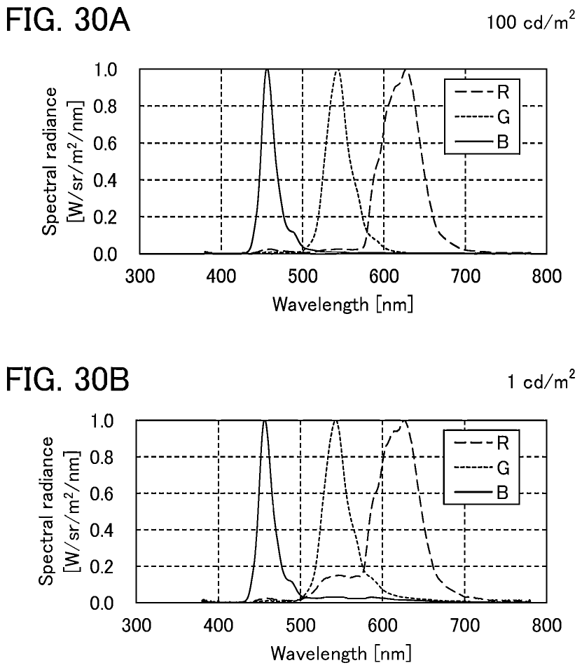

FIG. 30A and FIG. 30B show spectra measurement results of the display panel. The wavelength dependence of spectral radiant intensity was measured in a state where all the pixels of the display panel displayed red (R), green (G), or blue (B). FIG. 30A shows spectra when red (R), green (G), and blue (B) are displayed at 100 cd/m². FIG. 30B shows spectra when displaying red (R), green (G), or blue (B) at 1 cd/m². As shown in FIG. 30A and FIG. 30B, almost no color mixing is observed, and it can be confirmed that the display panel can achieve extremely high contrast and color rendering properties.

### REFERENCE NUMERALS

10A: display apparatus, 10B: display apparatus, 10C: display apparatus, 10D: display apparatus, 10E: display apparatus, 10F: display apparatus, 10X: display apparatus, 10Y: display apparatus, 10: display apparatus, 11: pixel circuit, 12B: light-emitting element, 12G: light-emitting element, 12R: light-emitting element, 12X: light-emitting element, 12: light-emitting element, 20B: subpixel, 20G: subpixel, 20R: subpixel, 20X: subpixel, 20: pixel, 21: wiring, 22a: wiring, 22b: wiring, 22c: wiring, 22d: wiring, 22: wiring, 23: wiring, 24: pixel electrode, 25: conductive layer, 27: conductive layer, 30a: transistor, 30b: transistor, 30c: transistor, 30d: transistor, 31a: semiconductor layer, 31b: semiconductor layer, 31c: semiconductor layer, 31d: semiconductor layer, 32: dummy layer, 200A: display apparatus, 200B: display apparatus, 200C: display apparatus, 200D: display apparatus, 201: substrate, 202: substrate, 203: wiring layer, 210: transistor, 211: conductive layer, 212: low-resistance region, 213: insulating layer, 214: insulating layer, 215: element isolation layer, 220A: transistor, 220B: transistor, 220: transistor, 221: semiconductor layer, 223: insulating layer, 224: conductive layer, 225: conductive layer, 226: insulating layer, 227: conductive layer, 231: insulating layer, 232: insulating layer, 233: insulating layer, 234: insulating layer, 235: insulating layer, 236: insulating layer, 237: insulating layer, 240: capacitor, 241: conductive layer, 242: conductive layer, 243: insulating layer, 250B: light-emitting element, 250G: light-emitting element, 250R: light-emitting element, 251: conductive layer, 252B: conductive layer, 252G: conductive layer, 252R: conductive layer, 253W: EL layer, 254: conductive layer, 255B: coloring layer, 255G: coloring layer, 255R: coloring layer, 256: insulating layer, 257: lens array, 258: insulating layer, 261: insulating layer, 262: insulating layer, 263: adhesive layer, 264: insulating layer, 271: conductive layer, 272: plug, 273: interlayer insulating layer, 310A: display apparatus, 311: substrate, 312: substrate, 313: display portion, 314: terminal portion, 320: layer, 321: transistor, 322: channel formation region, 330: driver circuit, 331: source driver circuit, 332: digital-to-analog converter circuit, 333: gate driver circuit, 334: level shifter, 335: amplifier circuit, 340: functional circuit, 341: memory device, 342a: color irregularity correction, 342b: upconversion, 342: GPU, memory device, 343: EL correction circuit, 344: timing controller, 345: CPU, 346: sensor controller, 347: power supply circuit, 350: layer, 351: pixel circuit, 352: transistor, 355: pixel circuit group, 360: layer, 361: light-emitting element, 370: display module, 371: printed wiring board, 372: terminal portion, 373: wire, 374: FPC, 375: connection portion, 380: input/output circuit, 390: pixel, 700: electronic device, 701: display panel, 702: housing, 703: optical member, 704: wearing portion, 705: camera, 706: display region, 711: lens, 712: reflective plate, 713: reflective surface, 715: light, 716: transmitted light, 750: electronic device, 751: display panel, 752: housing, 754: wearing portion, 755: shock-absorbing material, 756: lens, 757: input terminal, 758: output terminal, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, and 792: layer.

1. A display apparatus comprising:
a first wiring;
a second wiring;
a third wiring;
a pixel electrode;
an EL layer; and
an insulating layer,
wherein the first wiring extends in a first direction and is supplied with a source signal,
wherein the second wiring extends in a second direction intersecting with the first direction and is supplied with a gate signal,
wherein a constant potential is applied to the third wiring,
wherein the first wiring and the pixel electrode are provided to overlap with each other with the third wiring therebetween,
wherein the insulating layer comprises a portion in contact with part of a top surface of the pixel electrode and a portion in contact with a side surface of the pixel electrode,
wherein the EL layer comprises a first portion in contact with another part of the top surface of the pixel electrode and a second portion positioned over the insulating layer, and
wherein the second portion comprises a region whose thickness is half or less of thickness of the first portion.

2. A display apparatus comprising:
a first wiring;
a second wiring;
a third wiring;
a pixel electrode;
a first transistor;
a second transistor;
an EL layer; and
an insulating layer,
wherein the first wiring extends in a first direction and is supplied with a source signal,
wherein the second wiring extends in a second direction intersecting with the first direction and is supplied with a gate signal,
wherein a first potential is applied to the third wiring,
wherein the first wiring and the pixel electrode are provided to overlap with each other with the third wiring therebetween,
wherein one of a source and a drain of the first transistor is electrically connected to the first wiring, and a gate of the first transistor is electrically connected to the second wiring,
wherein one of a source and a drain of the second transistor is electrically connected to the pixel electrode, and the other of the source and the drain of the second transistor is electrically connected to the third wiring,
wherein the first transistor and the second transistor each comprise a semiconductor layer in which current flows in the first direction,
wherein the insulating layer comprises a portion in contact with part of a top surface of the pixel electrode and a portion in contact with a side surface of the pixel electrode,
wherein the EL layer comprises a first portion in contact with another part of the top surface of the pixel electrode and a second portion positioned over the insulating layer, and
wherein the second portion comprises a region whose thickness is half or less of thickness of the first portion.

3. A display apparatus comprising:
a first wiring;
a second wiring;
a third wiring;
a pixel electrode;
a first transistor;
a second transistor;
an EL layer; and
an insulating layer,
wherein the first wiring extends in a first direction and is supplied with a source signal,
wherein the second wiring extends in a second direction intersecting with the first direction and is supplied with a gate signal,
wherein a first potential is applied to the third wiring,
wherein the first wiring and the pixel electrode are provided to overlap with each other with the third wiring therebetween,
wherein one of a source and a drain of the first transistor is electrically connected to the first wiring, and a gate of the first transistor is electrically connected to the second wiring,
wherein one of a source and a drain of the second transistor is electrically connected to the pixel electrode, and the other of the source and the drain of the second transistor is electrically connected to the third wiring,
wherein the first transistor and the second transistor each comprise a semiconductor layer in which current flows in the second direction,
wherein the insulating layer comprises a portion in contact with part of a top surface of the pixel electrode and a portion in contact with a side surface of the pixel electrode,
wherein the EL layer comprises a first portion in contact with another part of the top surface of the pixel electrode and a second portion positioned over the insulating layer, and
wherein the second portion comprises a region whose thickness is half or less of thickness of the first portion.

4. The display apparatus according to claim 2, further comprising a plurality of dummy layers,
wherein the dummy layer comprises the same semiconductor material as the semiconductor layer,
wherein the dummy layer comprises a portion having substantially the same top surface shape as the semiconductor layer, and
wherein the plurality of dummy layers and the semiconductor layer are placed at a regular interval in the second direction.

5. The display apparatus according to claim 3, further comprising a plurality of dummy layers,
wherein the dummy layer comprises the same semiconductor material as the semiconductor layer,
wherein the dummy layer comprises a portion having substantially the same top surface shape as the semiconductor layer, and
wherein the plurality of dummy layers and the semiconductor layer are placed at a regular interval in the first direction.

6. The display apparatus according to claim 2, further comprising a fourth wiring, a third transistor, and a fourth transistor,
wherein one of a source and a drain of the third transistor is electrically connected to the fourth wiring, and the other of the source and the drain of the third transistor is electrically connected to a gate of the second transistor,
wherein one of a source and a drain of the fourth transistor is electrically connected to the fourth wiring, and the other of the source and the drain of the fourth transistor is electrically connected to the pixel electrode, and
wherein a second potential lower than the first potential is applied to the fourth wiring.

7. The display apparatus according to claim 2, further comprising a fifth transistor,
wherein the fifth transistor is a transistor whose channel is formed in silicon,
wherein the semiconductor layer comprises one or both of indium and zinc, and
wherein the first transistor and the second transistor are provided above the fifth transistor.

8. The display apparatus according to claim 1,
wherein the third wiring has a grid-like top surface shape, and the third wiring comprises a third portion extending in the first direction and a fourth portion extending in the second direction, and
wherein the pixel electrode and the first wiring are provided to overlap with each other with the third portion therebetween.

9. The display apparatus according to claim 1, further comprising a plurality of pixel electrodes,
wherein a light-emitting region is provided over each of the pixel electrodes, and
wherein the plurality of light-emitting regions are arranged so that one of the light-emitting regions is surrounded by six of the light-emitting regions in a plan view.

10. The display apparatus according to claim 9,
wherein the light-emitting region has a substantially hexagonal top surface shape, and
wherein the light-emitting region has a top surface shape in which interior angles of two opposite corners of six corners are each greater than 120° and interior angles of the other four of the six corners are each less than 120°.

11. The display apparatus according to claim 9,
wherein the light-emitting region has a substantially hexagonal top surface shape, and
wherein the light-emitting region has a top surface shape in which six interior angles are each 120°, lengths of two opposite sides of six sides are equal to each other, and lengths of the other four sides are equal to one another.

12. The display apparatus according to claim 9, wherein three adjacent light-emitting regions of the light-emitting regions are positioned to be on vertices of an isosceles triangle.

13. A display module comprising:
the display apparatus according to claim 1; and
a connector or an integrated circuit.

14. An electronic device comprising:
the display module according to claim 13; and
at least one of an antenna, a battery, a housing, a camera, a speaker, a microphone, a touch sensor, and an operation button.

15. The display apparatus according to claim 3, further comprising a fourth wiring, a third transistor, and a fourth transistor,
wherein one of a source and a drain of the third transistor is electrically connected to the fourth wiring, and the other of the source and the drain of the third transistor is electrically connected to a gate of the second transistor,
wherein one of a source and a drain of the fourth transistor is electrically connected to the fourth wiring, and the other of the source and the drain of the fourth transistor is electrically connected to the pixel electrode, and
wherein a second potential lower than the first potential is applied to the fourth wiring.

16. The display apparatus according to claim 3, further comprising a fifth transistor,
wherein the fifth transistor is a transistor whose channel is formed in silicon,
wherein the semiconductor layer comprises one or both of indium and zinc, and
wherein the first transistor and the second transistor are provided above the fifth transistor.

17. The display apparatus according to claim 2,
wherein the third wiring has a grid-like top surface shape, and the third wiring comprises a third portion extending in the first direction and a fourth portion extending in the second direction, and
wherein the pixel electrode and the first wiring are provided to overlap with each other with the third portion therebetween.

18. The display apparatus according to claim 3,
wherein the third wiring has a grid-like top surface shape, and the third wiring comprises a third portion extending in the first direction and a fourth portion extending in the second direction, and
wherein the pixel electrode and the first wiring are provided to overlap with each other with the third portion therebetween.

19. The display apparatus according to claim 2, further comprising a plurality of pixel electrodes,
wherein a light-emitting region is provided over each of the pixel electrodes, and
wherein the plurality of light-emitting regions are arranged so that one of the light-emitting regions is surrounded by six of the light-emitting regions in a plan view.

20. The display apparatus according to claim 3, further comprising a plurality of pixel electrodes,
wherein a light-emitting region is provided over each of the pixel electrodes, and
wherein the plurality of light-emitting regions are arranged so that one of the light-emitting regions is surrounded by six of the light-emitting regions in a plan view.
